(19) United States
(12) Patent Application Publication
(10) Pub. No.: US 2022/0384625 A1
(43) Pub. Date: Dec. 1, 2022

(54) MOS DEVICES WITH INCREASED SHORT CIRCUIT ROBUSTNESS

(71) Applicant: Purdue Research Foundation, West Lafayette, IN (US)

(72) Inventors: James Albert Cooper, Santa Fe, NM (US); Dallas Todd Morisette, Lafayette, IN (US); Madankumar Sampath, West Lafayette, IN (US)

(73) Assignee: Purdue Research Foundation, West Lafayette, IN (US)

(21) Appl. No.: 17/871,844

(22) Filed: Jul. 22, 2022

Related U.S. Application Data
(63) Continuation of application No. 16/438,055, filed on Jun. 11, 2019.
(60) Provisional application No. 62/684,618, filed on Jun. 13, 2018.

(51) Int. Cl. H01L 29/739; H03K 17/08; H01L 29/78; H03K 17/687; H03K 17/60

(52) U.S. Cl. CPC H01L 29/7397; H03K 17/08; H01L 29/7816; H03K 17/687; H03K 17/60

(57) ABSTRACT

A silicon carbide (SiC) metal oxide semiconductor (MOS) power device is disclosed which includes an SiC drain semiconductor region, an SiC drift semiconductor region coupled to the SiC drain semiconductor region, an SiC base semiconductor region coupled to the SiC drift semiconductor region, an SiC source semiconductor region coupled to the SiC base semiconductor region, a source electrode coupled to the SiC source semiconductor region, a drain electrode coupled to the SiC drain semiconductor region, a gate electrode, wherein voltage of the gate electrode with respect to the SiC base semiconductor region is less than or equal to about 12 V and thickness of the dielectric material is such that the electric field in the dielectric material is about 4 MV/cm when said gate voltage is about 12 V.

### CROSS-REFERENCE TO RELATED APPLICATIONS

The present patent application is a continuation of U.S. Non-Provisional application Ser. No. 16/438,055 which is related to and claims the priority benefit of U.S. Provisional Ser. No. 62/684,618 filed 13 Jun. 2018, the contents of each of which are hereby incorporated by reference in its entirety into the present disclosure.

### STATEMENT REGARDING GOVERNMENT FUNDING

This invention was made with government support under W911NF-15-2-0041 awarded by Army Research Lab. The government has certain rights in the invention.

### TECHNICAL FIELD

The present disclosure generally relates to electronic switches, and in particular, to power devices with increased short circuit robustness.

### BACKGROUND

This section introduces aspects that may help facilitate a better understanding of the disclosure. Accordingly, these statements are to be read in this light and are not to be understood as admissions about what is or is not prior art.

Referring to FIG. 14, a schematic of an electronic switching system 10 is shown which includes an electronic switch, e.g., a power metal oxide semiconductor field effect transistor (MOSFET), 12 and a load 14. The load 14 is coupled to a source. The electronic switch 12, which includes a control terminal 16, a first terminal 18 and second terminal 20 is coupled to the load 14 and the ground. The control terminal 16 controls the electronic switch by essentially establishing a path for current to flow between the first terminal 18 and the second terminal 20. The closing of the switch is shown to convey the concept. In actuality, when an appropriate voltage is applied to the control terminal 16, a channel is formed between the first and second terminals 18 and 20, thereby adaptable to pass the current therebetween. In the on state, the electronic switch 12 poses a resistance (identified as R_{ON}) 22 which when placed in series with a load resistance 24 in the load 14, establish the current (essentially, voltage of the source divided by the algebraic addition of the two resistances 22 and 24). Typically, the resistance of the resistor 22 is smaller than the resistance of the resistor 24. In case of a failure by the load 14, where the load is shorted (signified by the dotted line 26), a sudden rush of current passes through the electronic switch 12 which is essentially equal to the voltage of the source divided by the resistance of the resistor 22. This high level of current results in quick heating of the electronic switch 12 leading to its failure. The resistance of the resistor 22 plays a significant role in such heating. A low value of resistance (desired for normal operations, i.e., when the load is operating normally) can result in significantly higher current when the load is shorted; while too much resistance can result in negative results during normal operations.

Therefore, there is an unmet need for a novel power device arrangement that increases robustness of the power device to short circuit conditions without sacrificing the normal operational parameters, such as on resistance.

### SUMMARY

A metal-oxide-semiconductor (MOS) power device is disclosed. The MOS power device is a double-diffused MOS field effect transistor (DMOSFET). The power device includes a drain semiconductor region of a first conductivity type, a drift semiconductor region of the first conductivity type coupled to the drain semiconductor region, a base semiconductor region of a second conductivity type coupled to the drift semiconductor region and isolated by the drift semiconductor region from the drain semiconductor region, and a source semiconductor region of the first conductivity type coupled to the base semiconductor region and isolated by the base semiconductor region from the drift semiconductor region. The DMOSFET further includes a source electrode coupled to the source semiconductor region, a drain electrode coupled to the drain semiconductor region, and a gate electrode provided adjacent at least a portion of but isolated from i) the base semiconductor region, ii) the source semiconductor region, and iii) the drift semiconductor region by a dielectric material. The dielectric material has a thickness between 1 nm and 30 nm multiplied by a correction factor defined as a ratio of dielectric permittivity of the dielectric material and the permittivity of silicon dioxide. The DMOSFET is configured to withstand greater than 100 V between the drain electrode and the source electrode when substantially no current is flowing through the drain electrode.

Another MOS power device, is also disclosed. The MOS power device is an insulated gate bipolar transistor (IGBT) which is a planar gate device. The planar IGBT includes a collector semiconductor region of a first conductivity type, a drift semiconductor region of a second conductivity type coupled to the collector semiconductor region, a base semiconductor region of the first conductivity type coupled to the drift semiconductor region and isolated by the drift semiconductor region from the collector semiconductor region, and an emitter semiconductor region of the second conductivity type coupled to the base semiconductor region and isolated by the base semiconductor region from the drift semiconductor region. The planar IGBT also includes an emitter electrode coupled to the emitter semiconductor region, a collector electrode coupled to the collector semiconductor region, and a gate electrode provided adjacent at least a portion of but isolated from i) the base semiconductor region, ii) the emitter semiconductor region, and iii) the drift semiconductor region by a dielectric material. The dielectric material has a thickness between 1 nm and 30 nm multiplied by a correction factor defined as a ratio of dielectric permittivity of the dielectric material and the permittivity of silicon dioxide. The planar IGBT is configured to withstand greater than 100 V between the collector electrode and the emitter electrode when substantially no current is flowing through the collector electrode.

Another MOS power device is also disclosed. The MOS device is a superjunction DMOSFET. The superjunction DMOSFET includes a drain semiconductor region of a first conductivity type, a drift semiconductor region comprised of alternating slabs of semiconductor material of the first conductivity type and a second conductivity type, configured such that a first edge of each slab is coupled to the drain semiconductor region, a base semiconductor region of the second conductivity type coupled to a second edge of each of the alternating slabs of the drift semiconductor region and isolated by the drift semiconductor region from the drain semiconductor region, and a source semiconductor region of the first conductivity type coupled to the base semiconductor region and isolated by the base semiconductor region from the drift semiconductor region. The superjunction DMOSFET further includes a source electrode coupled to the source semiconductor region, a drain electrode coupled to the drain semiconductor region, and a gate electrode provided adjacent at least a portion of but isolated from i) the base semiconductor region, ii) the source semiconductor region, and iii) the drift semiconductor region by a dielectric material. The dielectric material has a thickness between 1 nm and 30 nm multiplied by a correction factor defined as a ratio of dielectric permittivity of the dielectric material and the permittivity of silicon dioxide. The superjunction DMOSFET is configured to withstand greater than 100 V between the drain electrode and the source electrode when substantially no current is flowing through the drain electrode.

Another MOS power device is also disclosed. The MOS device is a UMOSFET. The UMOSFET includes a drain semiconductor region of a first conductivity type, a drift semiconductor region of the first conductivity type coupled to the drain semiconductor region, a base semiconductor region of a second conductivity type coupled to the drift semiconductor region and isolated by the drift semiconductor region from the drain semiconductor region, and a source semiconductor region of the first conductivity type coupled to the base semiconductor region and isolated by the base semiconductor region from the drift semiconductor region. The UMOSFET further includes a source electrode coupled to the source semiconductor region, a drain electrode coupled to the drain semiconductor region, and a gate electrode provided adjacent at least a portion of but isolated from i) the base semiconductor region, ii) the source semiconductor region, and iii) the drift semiconductor region by a dielectric material. wherein at least a portion of the gate electrode and the dielectric material is trenched into the drift semiconductor region. The dielectric material has a thickness between 1 nm and 30 nm multiplied by a correction factor defined as a ratio of dielectric permittivity of the dielectric material and the permittivity of silicon dioxide. The UMOSFET is configured to withstand greater than 100 V between the drain electrode and the source electrode when substantially no current is flowing through the drain electrode.

Another MOS power device is also disclosed. The MOS device is a superjunction UMOSFET. The superjunction UMOSFET includes a drain semiconductor region of a first conductivity type, a drift semiconductor region comprised of alternating slabs of semiconductor material of the first conductivity type and a second conductivity type, configured such that a first edge of each slab is coupled to the drain semiconductor region, a base semiconductor region of the second conductivity type coupled to a second edge of each of the alternating slabs of the drift semiconductor region and isolated by the drift semiconductor region from the drain semiconductor region, and a source semiconductor region of the first conductivity type coupled to the base semiconductor region and isolated by the base semiconductor region from the drift semiconductor region. The superjunction UMOSFET also includes a source electrode coupled to the source semiconductor region, a drain electrode coupled to the drain semiconductor region, and a gate electrode provided above at least a portion of but isolated from i) the base semiconductor region, ii) the source semiconductor region, and iii) the drift semiconductor region by a dielectric material, wherein at least a portion of the gate electrode and the dielectric material is trenched into the drift semiconductor region. The dielectric material has a thickness between 1 nm and 30 nm multiplied by a correction factor defined as a ratio of dielectric permittivity of the dielectric material and the permittivity of silicon dioxide. The superjunction UMOSFET is configured to withstand greater than 100 V between the drain electrode and the source electrode when substantially no current is flowing through the drain electrode.

A power semiconductor device is also disclosed. The device includes a semiconductor region, a gate electrode separated from the semiconductor region by a dielectric material, wherein a load current passing through the device through two load terminals is controlled by the electric field induced by the gate electrode into the semiconductor region. A maximum load current permitted by the device is regulated by increasing capacitance of the dielectric material and by simultaneously reducing the maximum gate drive voltage so as to keep the induced electric field in the dielectric material at or below a predetermined threshold. The dielectric material has a thickness between 1 nm and 30 nm multiplied by a correction factor defined as the dielectric permittivity of the insulating film divided by the dielectric permittivity of silicon dioxide. The device is configured to withstand greater than 100 V between the two load terminals carrying the load current.

### BRIEF DESCRIPTION OF DRAWINGS

FIG. 1 is a symbolic representation of a power device, e.g., a power metal oxide semiconductor field effect transistor (MOSFET).

FIG. 2 is a schematic of the MOSFET of FIG. 1 with a load.

FIG. 3 is a cross sectional view of a MOS power device, and in particular a double-diffused MOS field effect transistor (DMOSFET).

FIG. 4 is a cross sectional view of a planar insulated gate bipolar transistor (IGBT).

FIG. 5 is a cross sectional view of a superjunction DMOSFET.

FIG. 6 is a cross sectional view of a lateral DMOSFET.

FIG. 7 is a cross sectional view of a lateral IGBT.

FIG. 8 is a graph of drain current I_{D} of a MOSFET as a function of V_{DS} for a gate voltage greater than the threshold voltage V_{T}.

FIG. 9 is a graph of calculated current density vs. drain voltage curves for a 900 V SiC DMOSFET with gate oxide thicknesses varying from 5-50 nm (one graph for each of 5 nm, 15 nm, 30 nm, and 50 nm).

FIG. 10 is a graph of estimated increase in short circuit withstand time with this decrease in oxide thickness.

FIG. 11 is a cross sectional view of a UMOSFET.

FIG. 12 is a cross sectional view of a superjunction UMOSFET.

FIG. 13 is cross sectional views of a trench gate IGBT.

FIG. 14 is a schematic of an electronic switching system.

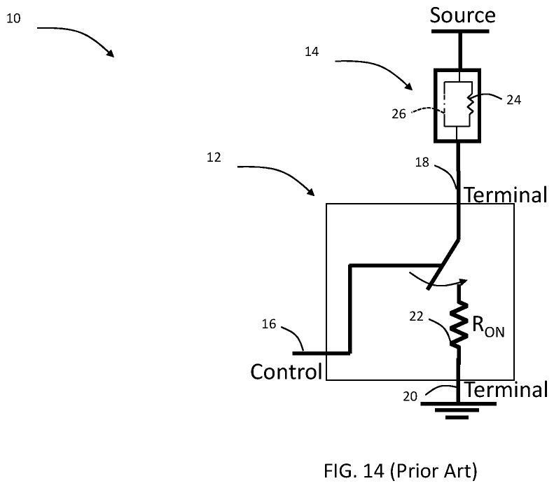

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

In the present disclosure, the term “about” can allow for a degree of variability in a value or range, for example, within 10%, within 5%, or within 1% of a stated value or of a stated limit of a range.

In the present disclosure, the term “substantially” can allow for a degree of variability in a value or range, for example, within 90%, within 95%, or within 99% of a stated value or of a stated limit of a range.

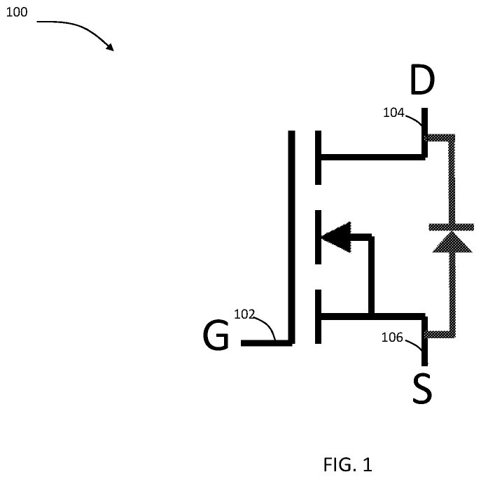

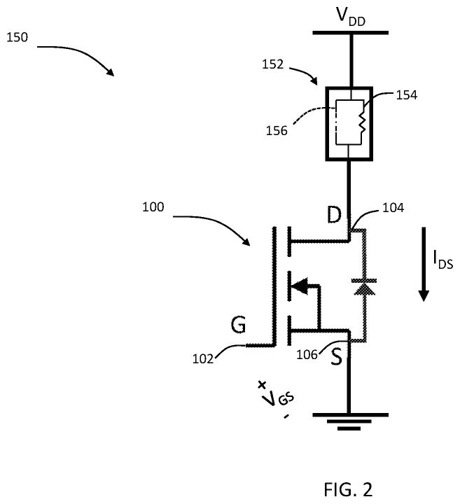

Referring to FIG. 1, a power device 100, e.g., a power metal oxide semiconductor field effect transistor (MOSFET) is shown, as known to a person having ordinary skill in the art, including three terminals gate 102, drain 104, and source 106. In the off-state, the power device 100 blocks current passing between the drain 104 and source 106 up to its maximum rated voltage while allowing only a negligible leakage current to flow. In the normal on-state, the power device 100 permits a high current to flow between the drain 104 and source 106, limited by the load resistance (see FIG. 2) of the circuit to which it is connected and the on-resistance of the power device 100, further described below. In either case the resulting power dissipation in the device remains low enough to prevent thermal damage to the device. In the power device 100 and many other power semiconductor devices, the on-state current is controlled by a metal-oxide-semiconductor (MOS) structure. This structure provides a high input impedance at the gate 102 that is desirable for circuit design considerations (i.e., improvement over bipolar devices requiring continuous electrical current to activate the device, i.e., to turn it on). Examples of MOS-controlled devices include the power MOS field effect transistors (MOSFETs, e.g., silicon carbide MOSFET (SiC MOSFET)), insulated-gate bipolar transistors (IGBTs), and MOS-controlled thyristors.

Referring to FIG. 2, an electronic switching system 150 is shown with the power device 100 of FIG. 1 shown as being coupled to a load 152. The load 152 includes a load resistor 154, which as discussed above limits the current passing through the power device 100 (shown as I_{DS}) when in the on state. When the power device 100 is in the on state, a channel is created (described below), allowing current to pass from the drain 104 to the source 106. The power device 100 is fully on when sufficient voltage is applied to the gate such that

V_{GS}>V_{T}, where

V_{GS} is the voltage between the gate 102 and the source 106 terminals, and
V_{T} is a threshold voltage which depends on the power device 100 and is the threshold value of V_{GS} above which the power device 100 begins to conduct load current when the drain-to-source voltage Vds>0.

However, if the load resistance suddenly drops (as shown in the dashed line in FIG. 2, going from the load resistor 154 to the shorted state 156), for instance due to a short in the winding of a motor coil, the power device 100 would be suddenly subjected to both high voltage of the supply (V_{DD}) and high current, producing an unsustainably high internal power dissipation. Under these conditions, the current passing between drain and source is considered to be at saturation. The limiting current density when the power device 100 is in saturation can be written

J_{load,sat}=I_{DSAT}/A=(V_{GS}−V_{T})/2R_{ch,sp}, where

V_{GS} is the gate-to-source voltage,
J_{DSAT}=I_{DSAT}/A is the saturated drain current density, and
R_{ch,sp} is product of channel resistance R_{ch} and the unit cell area of the power device structure. Since the power that the device dissipates internally in the on-state is proportional to R_{ch,sp}, it is a goal of the power device designer to reduce R_{ch,sp}, which increases the saturation load current J_{load,sat}. This condition will ultimately lead to the thermal destruction of the power device 100 if the condition is not interrupted quickly. Power electronic circuits generally include a short-circuit protection scheme to mitigate this condition, in which the gate driver turns the power transistor off when a short circuit condition is detected. However, this process takes a finite amount of time, typically on the order of 1-10 μs. A robust power transistor must be able to absorb the energy of this event without failure. The ability of a transistor to survive these events is characterized by the short-circuit withstand time, which is defined as the maximum time that the device can be subjected to the short-circuit condition before failure occurs. While the criteria for “failure” has not been well defined in the prior art, failure according to the present disclosure includes failure due to unacceptable changes in device parameters such that the device no longer meets its specifications, or the introduction of latent damage that reduces the long-term/lifetime reliability of the device, while difficult to detect in practice.

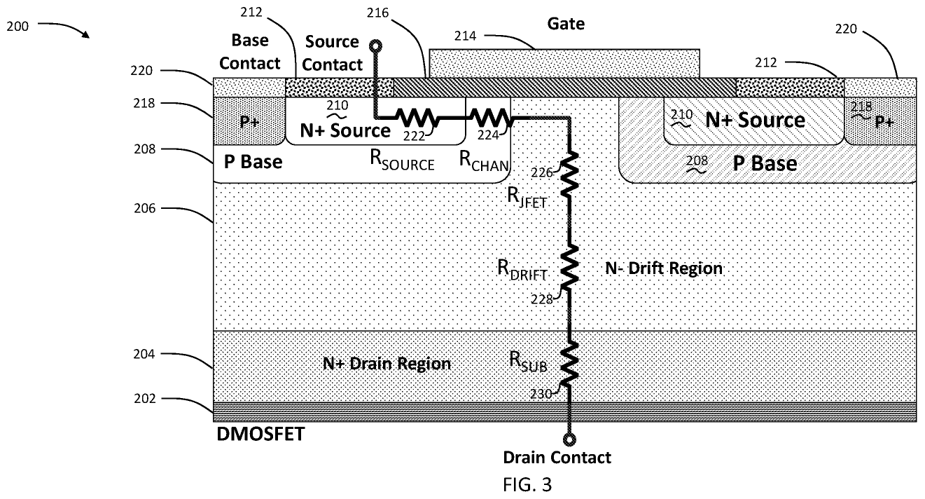

Therefore, from one perspective, two important parameters of a power semiconductor device of interest in studying robustness of the device are the specific on-resistance R_{on,sp} and the short-circuit withstand time (SCWT). The specific on-resistance includes several internal resistances (see FIG. 3, where an exemplary schematic is shown of power device, e.g., a MOSFET) that are additive, and one of these is the channel specific resistance R_{ch,sp} (shown in FIG. 3 as R_{CHAN}) In SiC, due to the low mobility of electrons in the MOS channel, the channel resistance can be the dominant term. As discussed above, the SCWT is the length of time the device can survive in the on-state if the load is suddenly shorted (see FIG. 2, going from the load resistor 154 to the shorted state 156). If this happens, the terminal voltage across the device (i.e., V_{DS}, voltage across terminals 104 and 106) rises to the supply voltage, V_{DD} (e.g., above 10 kV, depending on the application), and the load terminal current (i.e., the current entering the terminal 104) rises to the saturation current J_{load,sat}. The power dissipated in the semiconductor is the product of the terminal current and terminal voltage, and in some cases can be in the hundreds of kW. This sudden increase in current through the power device 100 and voltage across it, causes rapid internal heating, leading to failure of the power device 100. Thus, the SCWT is the length of time the device can survive before failure. As a result, it is the goal of the designer to minimize R_{on,sp} and maximize the SCWT, but as provided herein, these are conflicting goals, since reducing R_{ch,sp} increases J_{load,sat} which reduces SCWT.

The designer cannot sacrifice on-state performance of the device by increasing R_{on,sp} in order to reduce SCWT, since increasing R_{on,sp} has deleterious effects for normal operations of the power device 100 (i.e., under normal working conditions and not short-circuit conditions). The present disclosure breaks the relationship between R_{ch,sp} and J_{load,sat}, allowing the designer to reduce J_{load,sat} without increasing R_{on,sp}.

A metal-oxide semiconductor (MOS) power device's input structure includes a gate insulator between a controlling electrode, i.e., the gate, and the surface of the semiconductor, i.e., a source region, base region, or drift region shown in FIG. 3. Referring To FIG. 3, a cross sectional view of a metal-oxide-semiconductor (MOS) power device 200, and in particular a double-diffused MOS field effect transistor (DMOSFET), is shown. It should be appreciated that the term DMOSFET originated with double-diffused silicon. While diffusion is impractical in SiC and the above-referenced SiC power device of the present disclosure are formed by double implantation, the same acronym as the silicon device is used for SiC. The MOS power device 200 includes a drain electrode 202 (identified as “Drain Contact”) in electrical contact with a drain semiconductor region 204 (shown as “N+ Drain Region”) of a first conductivity type (N type shown, however as explained below the first conductivity type can be P type while a second conductivity type be N type). The material of the drain semiconductor region 204 can be doped silicon, doped silicon carbide, or other suitable semiconductor material (e.g., gallium arsenide (GaAs) or gallium nitride (GaN)). More is discussed below regarding the doping level. The MOS Power device 200 also includes a drift semiconductor region 206 of the first conductivity type (shown as “N-Drift Region”, however as explained below the first conductivity type can be P type while the second conductivity type can be N type). The drift semiconductor region 206 is coupled to the drain semiconductor region 204. The material of the drift semiconductor region 206 can be doped silicon, doped silicon carbide, or other suitable semiconductor material (e.g., gallium arsenide (GaAs) or gallium nitride (GaN)). The MOS power device 200 further includes a base semiconductor region 208 of the second conductivity type (shown as “P Base”, however as explained below the second conductivity type can be N type while the first conductivity type can be P type). The base semiconductor region 208 is coupled to the drift semiconductor region 206 through the pn junction at the interface between these two regions. The material of the base semiconductor region 208 can be doped silicon, doped silicon carbide, or other suitable semiconductor material. The MOS power device 200 further includes a source semiconductor region 210 of the first conductivity type (shown as “N+ Source”, however as explained below the first conductivity type can be P type while the second conductivity type can be N type). The source semiconductor region 210 is coupled to the base semiconductor region 208 and isolated by the base semiconductor region 208 from the drift semiconductor region 206. The material of the source semiconductor region 210 can be doped silicon, doped silicon carbide, or other suitable semiconductor material. The MOS power device 200 further includes a source electrode 212 (shown as “Source Contact”) that is coupled to the source semiconductor region 210, making electrical contact therewith. The MOS power device 200 further includes a gate electrode 214 (shown simply as “Gate”) that is provided adjacent at least a portion of but isolated from i) the base semiconductor region 208, ii) the source semiconductor region 210, and iii) the drift semiconductor region 206 by a dielectric material 216. The dielectric material 216 has a thickness between 1 nm and 30 nm (or between 1 nm and 25 nm, or between 1 nm and 20 nm, or between 1 nm and 15 nm, or between 1 nm and 10 nm, or between 1 and 5 nm) multiplied by a correction factor defined as a ratio of dielectric permittivity of the dielectric material and the permittivity of silicon dioxide. The drift semiconductor region 206 has a sufficient thickness and doping to withstand greater than e.g., 100 V (this value depends on the semiconductor material—in silicon the drift region may only be designed to withstand greater than 20-30 V; in SiC, the drift region typically withstands more than 400-500 V; and GaN is above 50-100 V) between the drain electrode 202 and the source electrode 212 when substantially no current is flowing through the drain electrode 202. The MOS power device 200 further includes a semiconductor region 218 of the second conductivity type (shown as “P+”, however as explained below the second conductivity type can be N type while the first conductivity type be P type). The semiconductor region 218 is coupled to the base semiconductor region 208 and isolated by the base semiconductor region 208 from the drift semiconductor region 206. The material of the semiconductor region 218 can be doped silicon, doped silicon carbide, or other suitable semiconductor material. The MOS power device 200 further includes a base contact 220 (shown as “Base Contact”) that is coupled to the semiconductor region 218, making electrical contact therewith.

If the gate-to-source voltage (V_{GS}) is above the threshold voltage V_{T}, a conducting channel (not shown, but known to a person having ordinary skill in the art) is induced along the surface of the semiconductor under the gate and the power device turns on. The gate insulator (i.e., the dielectric material 216) is a dielectric, and the most common dielectric is SiO₂. Other dielectric materials could also be used, for example Al₂O₃, Si₃N₄, HfO₂, ZrO₂, or layered combinations thereof.

Each dielectric material can be characterized in terms of two electric fields, the breakdown field (i.e., critical field) E_{CR} where the dielectric fails and no longer acts as an insulator, and the maximum reliable field E_{REL} beyond which the dielectric does not satisfy long-term reliability requirements. For SiO₂, E_{CR} is about 10 MV/cm and E_{REL} is about 4 MV/cm. Other dielectrics can each be characterized with particular values for E_{CR} and E_{REL}. The electric field in the dielectric material is given by:

Eᵢₙₛ=(V_{G}−φ_{GS}−2ψ_{F})/tᵢₙₛ

where V_{G} is the voltage between the gate and the semiconductor in volts,
φ_{GS} is the work function difference between the gate material and the semiconductor in volts,
ψ_{F} is the bulk Fermi potential of the semiconductor material (determined by its doping) in volts, and
tᵢₙₛ is the thickness of the dielectric material between the gate and the semiconductor in centimeters.

In the event of a short circuit, shown as a dashed line in FIG. 2 in the load 152, a high internal power dissipation occurs which causes extremely rapid adiabatic heating of the power device 100 or 200. The generated heat does not have sufficient time to diffuse outward to any attached cooling apparatus (e.g. a heat sink) via normal thermal conduction before the device fails. The temperature rise ΔT that occurs inside the device during a short-circuit event of duration t_{sc} seconds can therefore be estimated as:

$$Δ T = \frac{P}{ρ {C}_{p} V} {t}_{s c} \qquad ( 1 )$$

where P is the power dissipated during the short circuit event in watts,
ρ is the density of the semiconductor material in g/cm³,
t_{sc} is the short circuit withstand time,
Cₚ is the specific heat capacity in J/g/° C. of the semiconductor material, and
V is the heated volume of the device in cm³. The power dissipation is simply the current flowing in the device multiplied by the voltage across the drain and source terminals, i.e., P=I_{D}×V_{DS}.

In the MOS power device 200 shown in FIG. 3, the dielectric material 216 includes one or more layers of silicon dioxide, aluminum oxide, zirconium oxide, hafnium oxide, gallium oxide, lanthanum oxide, lanthanum aluminum oxide, beryllium oxide, or other suitable dielectric.

In the MOS power device shown in FIG. 3, the material of the source, drain, and gate electrodes 212, 214, and 202, respectively, includes one or more of copper, silver, gold, carbon, graphite, nickel, titanium, aluminum, polysilicon, and graphene. According to one embodiment, the ohmic metal used on N-type regions such as the source and drain is nickel. The ohmic metal used on P-type regions such as the base is aluminum or nickel. It should be appreciated that these metals are used in SiC, while other metals may be used for other MOSFETs such as silicon MOSFETs and GaN MOSFETs. These metals are annealed at a high temperature, e.g., about 1000° C.—however, lower temperatures may be acceptable for various other semiconductor material, e.g., GaN—to form ohmic contacts, then they are covered with a thick (4-5 μm) conductive metal such as aluminum. A thin layer of titanium is typically used for adhesion, covered with a thicker layer of aluminum containing about 0.5% copper.

In the MOS power device 200 shown in FIG. 3, the drift semiconductor region 206 is in contact with the drain semiconductor region 204.

In the MOS power device 200 shown in FIG. 3, the base semiconductor region 208 is in contact with the drift semiconductor region 206.

In the MOS power device 200 shown in FIG. 3, the source semiconductor region 210 is in contact with the base semiconductor region 208.

In the MOS power device 200 shown in FIG. 3, the first conductivity type is N-type and the second conductivity type is P-type.

In the MOS power device 200 shown in FIG. 3, the first conductivity type is P-type and the second conductivity type is N-type.

In the MOS power device 200 shown in FIG. 3, the drain semiconductor region 204 has a dopant level higher than a dopant level of the drift semiconductor region 206.

In the MOS power device 200 shown in FIG. 3, the source semiconductor region 210 has a dopant level higher than a dopant level of the drift semiconductor region 206.

Referring to FIG. 3, the resistance of the MOS power device 200 in the on state is represented by five units. These are: R_{SOURCE} 222, R_{CHAN} 224, R_{JFET} 226, R_{DRIFT} 228, and R_{SUB} 230, representing the source portion, the channel portion, the JFET region defined as the portion of the drift region between two adjacent base regions, the drift region portion, and the substrate portion of the MOS power device 200, respectively.

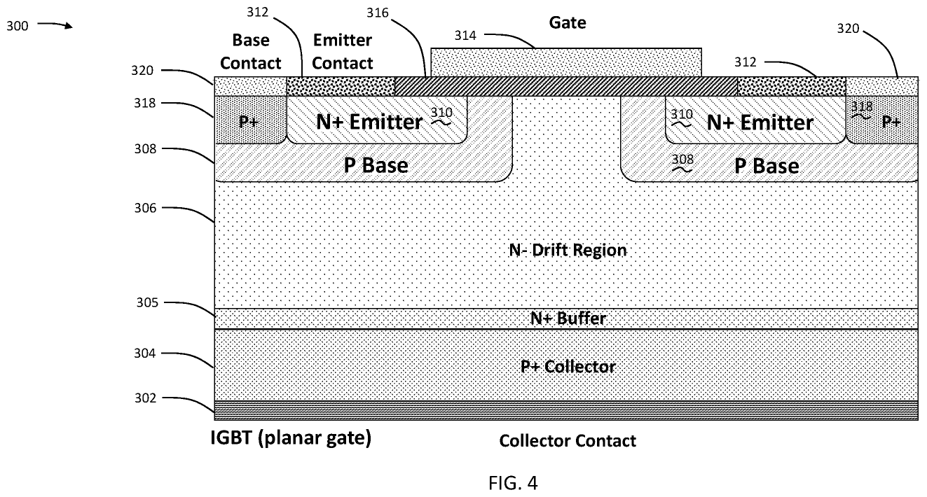

Referring to FIG. 4, a cross sectional view of a planar (vertical) insulated gate bipolar transistor (IGBT) 300 is shown. The description provided above for the DMOSFET in relationship with FIG. 3 applies to the IGBT device of FIG. 4 with the apparent differences (e.g., collector semiconductor region instead of the drain semiconductor region, emitter semiconductor region instead of the source semiconductor region, collector electrode, shown as “Collector Contact”, instead of the drain electrode, and emitter electrode, shown as “Emitter Contact”, instead of the source electrode).

Referring to FIG. 4, the vertical IGBT power device 300 includes a collector electrode 302 in electrical contact with a collector semiconductor region 304 (shown as “P+ Collector Region”) of a first conductivity type (P type shown, however as explained below the first conductivity type can be N type while a second conductivity type can be P type). The material of the collector semiconductor region 304 can be doped silicon, doped silicon carbide, or other suitable semiconductor material. More is discussed below regarding the doping level. The vertical IGBT power device 300 further includes a buffer layer 305 (shown as N+ Buffer) of the second conductivity type (N type shown, however as explained below the first conductivity type can be N type while the second conductivity type can be P type). The vertical IGBT power device 300 also includes a drift semiconductor region 306 of the second conductivity type (shown as “N-Drift Region”, however as explained below the first conductivity type can be N type while a second conductivity type can be P type). The drift semiconductor region 306 is coupled to the collector semiconductor region 304 via the buffer layer 305. The material of the drift semiconductor region 306 can be doped silicon, doped silicon carbide, or other suitable semiconductor material. The vertical IGBT power device 300 further includes a base semiconductor region 308 of the first conductivity type (shown as “P Base”, however as explained below the second conductivity type can be p type while the first conductivity type can be N type). The base semiconductor region 308 is coupled to the drift semiconductor region 306 through the pn junction at the interface between these two regions. The material of the base semiconductor region 308 can be doped silicon, doped silicon carbide, or other suitable semiconductor material. The vertical IGBT power device 300 further includes an emitter semiconductor region 310 of the second conductivity type (shown as “N+ Emitter”, however as explained below the first conductivity type can be N type while the second conductivity type can be P type). The emitter semiconductor region 310 is coupled to the base semiconductor region 308 and isolated by the base semiconductor region 308 from the drift semiconductor region 306. The material of the emitter semiconductor region 310 can be doped silicon, doped silicon carbide, or other suitable semiconductor material. The vertical IGBT power device 300 further includes an emitter electrode 312 (shown as “Emitter Contact”) that is coupled to the emitter semiconductor region 310, making electrical contact therewith. The vertical IGBT power device 300 further includes a gate electrode 314 (shown simply as “Gate”) that is provided adjacent at least a portion of but isolated from i) the base semiconductor region 308, ii) the emitter semiconductor region 310, and iii) the drift semiconductor region 306 by a dielectric material 316. The dielectric material 316 has a thickness between 1 nm and 30 nm (or between 1 nm and 25 nm, or between 1 nm and 20 nm, or between 1 nm and 15 nm, or between 1 nm and 10 nm, or between 1 and 5 nm) multiplied by a correction factor defined as a ratio of dielectric permittivity of the dielectric material and the permittivity of silicon dioxide. The drift semiconductor region 306 has a sufficient thickness and doping to withstand greater than e.g., 100 V (this value depends on the semiconductor material—in silicon the drift region may only be designed to withstand greater than 20-30 V; in SiC, the drift region typically withstands more than 400-500 V; and GaN is above 50-100 V) between the collector electrode 302 and the emitter electrode 312 when substantially no current is flowing through the collector electrode 302. The vertical IGBT power device 300 further includes a semiconductor region 318 of the first conductivity type (shown as “P+”, however as explained below the second conductivity type can be P type while the first conductivity type can be N type). The semiconductor region 318 is coupled to the base semiconductor region 308. The material of the semiconductor region 318 can be doped silicon, doped silicon carbide, or other suitable semiconductor material. The vertical IGBT power device 300 further includes a base contact 320 (shown as “Base Contact”) that is coupled to the semiconductor region 318, making electrical contact therewith.

The gate insulator (i.e., the dielectric material 316) is a dielectric, and the most common dielectric is SiO₂. Other dielectric materials could also be used, for example Al₂O₃, Si₃N₄, HfO₂, ZrO₂, or layered combinations thereof.

Each dielectric material can be characterized in terms of two electric fields, the breakdown field (i.e., critical field) E_{CR} where the dielectric fails and no longer acts as an insulator, and the maximum reliable field E_{REL} beyond which the dielectric does not satisfy long-term reliability requirements. For SiO₂, E_{CR} is about 10 MV/cm and E_{REL} is about 4 MV/cm. Other dielectrics can each be characterized with particular values for E_{CR} and E_{REL}.

In the event of a short circuit, shown as a dashed line in FIG. 2 in the load 152, a high internal power dissipation occurs which causes extremely rapid adiabatic heating of the power device 100 or 300. The generated heat does not have sufficient time to diffuse outward to any attached cooling apparatus (e.g. a heat sink) via normal thermal conduction before the device fails. The temperature rise ΔT that occurs inside the device during a short-circuit event of duration t_{sc} seconds can therefore be estimated as provide in equation (1) above.

In the vertical IGBT power device 300 shown in FIG. 4, the dielectric material 316 includes one or more layers of silicon dioxide, aluminum oxide, zirconium oxide, hafnium oxide, gallium oxide, lanthanum oxide, lanthanum aluminum oxide, beryllium oxide, or other suitable materials.

In the vertical IGBT power device 300 shown in FIG. 4, the material of the emitter, collector, and gate electrodes 312, 314, and 302, respectively, includes one or more of copper, silver, gold, carbon, graphite, nickel, titanium, aluminum, polysilicon, and graphene. According to one embodiment, the ohmic metal used on N-type regions such as the emitter and collector is nickel. It should be appreciated that these metals are used in SiC, while other metals may be used for other MOSFETs such as silicon MOSFETs and GaN MOSFETs. These metals are annealed at a high temperature, e.g., about 1000° C.—however, lower temperatures may be acceptable for various other semiconductor material, e.g., GaN—to form ohmic contacts, then they are covered with a thick (4-5 μm) conductive metal such as aluminum. A thin layer of titanium is typically used for adhesion, covered with a thicker layer of aluminum containing about 0.5% copper.

In the vertical IGBT power device 300 shown in FIG. 4, the buffer layer 305 is in contact with the collector semiconductor region 304.

In the vertical IGBT power device 300 shown in FIG. 4, the drift semiconductor region 306 is in contact with the buffer layer 305.

In the vertical IGBT power device 300 shown in FIG. 4, the base semiconductor region 308 is in contact with the drift semiconductor region 306.

In the vertical IGBT power device 300 shown in FIG. 4, the emitter semiconductor region 310 is in contact with the base semiconductor region 308.

In the vertical IGBT power device 300 shown in FIG. 4, the first conductivity type is P type and the second conductivity type is N type.

In the vertical IGBT power device 300 shown in FIG. 4, the first conductivity type is N type and the second conductivity type is P type.

In the vertical IGBT power device 300 shown in FIG. 4, the collector semiconductor region 304 has a dopant level higher than a dopant level of the drift semiconductor region 306.

In the vertical IGBT power device 300 shown in FIG. 4, the emitter semiconductor region 310 has a dopant level higher than a dopant level of the drift semiconductor region 306.

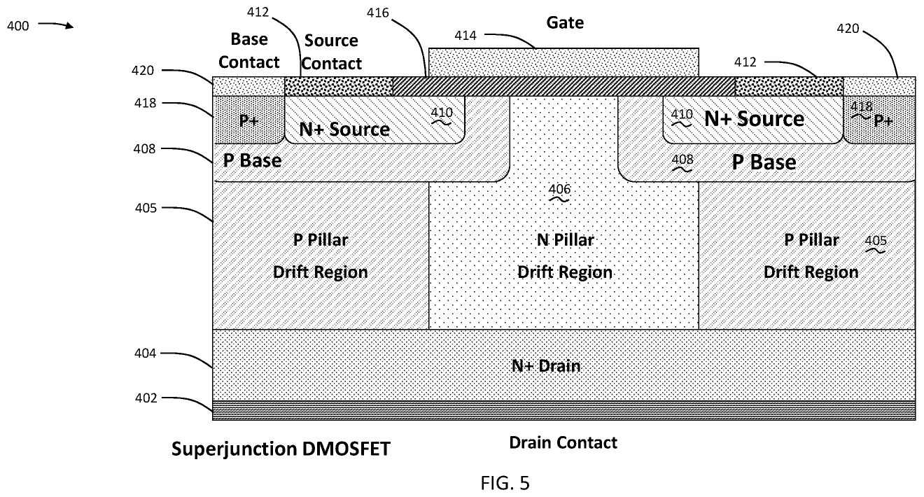

Referring to FIG. 5, a cross sectional view of a superjunction DMOSFET is shown. The description provided above for the DMOSFET in relationship with FIG. 3 applies to the superjunction DMOSFET device of FIG. 5 with the apparent differences (e.g., the drift region is comprised of alternating stacks, shown as “P Pillar”, “N Pillar”, and “P Pillar” of alternating polarities).

The MOS power device 400 includes a drain electrode 402 (identified as “Drain Contact”) in electrical contact with a drain semiconductor region 404 (shown as “N+ Drain”) of a first conductivity type (N type shown, however as explained below the first conductivity type can be P type while a second conductivity type can be N type). The material of the drain semiconductor region 404 can be doped silicon, doped silicon carbide, or other suitable semiconductor material. More is discussed below regarding the doping level. The MOS Power device 400 also includes alternating stacks, shown as “P Pillar”, “N Pillar”, and “P Pillar” of alternating conductivity types 405 and 406 of the second conductivity type and the first conductivity type (shown as “P Pillar Drift Region” and “N Pillar Drift Region”, however, as explained below the first conductivity type can be P type while a second conductivity type can be N type). The drift semiconductor regions 405 and 406 are coupled to the drain semiconductor region 404. The material of the drift semiconductor regions 405 and 406 can be doped silicon, doped silicon carbide, or other suitable semiconductor material. The MOS power device 400 further includes a base semiconductor region 408 of the second conductivity type (shown as “P Base”, however as explained below the second conductivity type can be N type while the first conductivity type can be P type). The base semiconductor region 408 is coupled to the drift semiconductor region 405 and isolated from the drain semiconductor region 404 by the pn junction at the interface between base region 408 and drift region 406. The material of the base semiconductor region 408 can be doped silicon, doped silicon carbide, or other suitable semiconductor material. The MOS power device 400 further includes a source semiconductor region 410 of the first conductivity type (shown as “N+ Source”, however as explained below the first conductivity type can be P type while the second conductivity type can be N type). The source semiconductor region 410 is coupled to the base semiconductor region 408 and isolated by the base semiconductor region 408 from the drift semiconductor regions 405 and 406. The material of the source semiconductor region 410 can be doped silicon, doped silicon carbide, or other suitable semiconductor material. The MOS power device 400 further includes a source electrode 412 (shown as “Source Contact”) that is coupled to the source semiconductor region 410, making electrical contact therewith. The MOS power device 400 further includes a gate electrode 414 (shown simply as “Gate”) that is provided adjacent at least a portion of but isolated from i) the base semiconductor region 408, ii) the source semiconductor region 410, and iii) the drift semiconductor region 406 by a dielectric material 416. The dielectric material 416 has a thickness between 1 nm and 30 nm (or between 1 nm and 25 nm, or between 1 nm and 20 nm, or between 1 nm and 15 nm, or between 1 nm and 10 nm, or between 1 and 5 nm) multiplied by a correction factor defined as a ratio of dielectric permittivity of the dielectric material and the permittivity of silicon dioxide. The drift semiconductor regions 405 and 406 have a sufficient thickness and doping to withstand greater than e.g., 100 V (this value depends on the semiconductor material—in silicon the drift region may only be designed to withstand greater than 20-30 V; in SiC, the drift region typically withstands more than 400-500 V; and GaN is above 50-100 V) between the drain electrode 402 and the source electrode 412 when substantially no current is flowing through the drain electrode 402. The MOS power device 400 further includes a semiconductor region 418 of the second conductivity type (shown as “P+ Source”, however as explained below the second conductivity type can be N type while the first conductivity type can be P type). The semiconductor region 418 is coupled to the base semiconductor region 408 and isolated by the base semiconductor region 408 from the drift semiconductor regions 405 and 406. The material of the semiconductor region 418 can be doped silicon, doped silicon carbide, or other suitable semiconductor material. The MOS power device 400 further includes a base contact 420 (shown as “Base Contact”) that is coupled to the semiconductor region 418, making electrical contact therewith.

If the gate-to-source voltage (V_{GS}) is above the threshold voltage V_{T}, a conducting channel (not shown, but known to a person having ordinary skill in the art) is induced along the surface of the semiconductor under the gate and the power device turns on. The gate insulator (i.e., the material 416) is a dielectric, and the most common dielectric is SiO₂. Other dielectric materials could also be used, for example Al₂O₃, Si₃N₄, HfO₂, ZrO₂, or layered combinations thereof.

Each dielectric material can be characterized in terms of two electric fields, the breakdown field (i.e., critical field) E_{CR} where the dielectric fails and no longer acts as an insulator, and the maximum reliable field E_{REL} beyond which the dielectric does not satisfy long-term reliability requirements. For SiO₂, E_{CR} is about 10 MV/cm and E_{REL} is about 4 MV/cm. Other dielectrics can each be characterized with particular values for E_{CR} and E_{REL}.

In the event of a short circuit, shown as a dashed line in FIG. 2 in the load 152, a high internal power dissipation occurs which causes extremely rapid adiabatic heating of the power device 100 or 400. The generated heat does not have sufficient time to diffuse outward to any attached cooling apparatus (e.g. a heat sink) via normal thermal conduction before the device fails. The temperature rise ΔT that occurs inside the device during a short-circuit event of duration t_{sc} seconds can therefore be estimated using equation (1) provided above.

In the MOS power device 400 shown in FIG. 5, the dielectric material 416 includes one or more layers of silicon dioxide, aluminum oxide, zirconium oxide, hafnium oxide, gallium oxide, lanthanum oxide, lanthanum aluminum oxide, and beryllium oxide.

In the MOS power device shown in FIG. 5, the material of the source, drain, and gate electrodes 412, 414, and 402, respectively, includes one or more of copper, silver, gold, carbon, graphite, nickel, titanium, aluminum, polysilicon, and graphene. According to one embodiment, the ohmic metal used on N-type regions such as the source and drain is nickel. The ohmic metal used on P-type regions such as the base is aluminum or nickel. It should be appreciated that these metals are used in SiC, while other metals may be used for other MOSFETs such as silicon MOSFETs and GaN MOSFETs. These metals are annealed at a high temperature, e.g., about 1000° C.—however, lower temperatures may be acceptable for various other semiconductor material, e.g., GaN—to form ohmic contacts, then they are covered with a thick (4-5 μm) conductive metal such as aluminum. A thin layer of titanium is typically used for adhesion, covered with a thicker layer of aluminum containing about 0.5% copper.

In the MOS power device 400 shown in FIG. 5, the drift semiconductor regions 405 and 406 are in contact with the drain semiconductor region 404.

In the MOS power device 400 shown in FIG. 5, the base semiconductor region 408 is in contact with the drift semiconductor regions 405 and 406.

In the MOS power device 400 shown in FIG. 5, the source semiconductor region 410 is in contact with the base semiconductor region 408.

In the MOS power device 400 shown in FIG. 5, the first conductivity type is N-type and the second conductivity type is P-type.

In the MOS power device 400 shown in FIG. 5, the first conductivity type is P-type and the second conductivity type is N-type.

In the MOS power device 400 shown in FIG. 5, the drain semiconductor region 404 has a dopant level higher than a dopant level of the drift semiconductor regions 405 or 406.

In the MOS power device 400 shown in FIG. 5, the source semiconductor region 410 has a dopant level higher than a dopant level of the drift semiconductor regions 405 or 406.

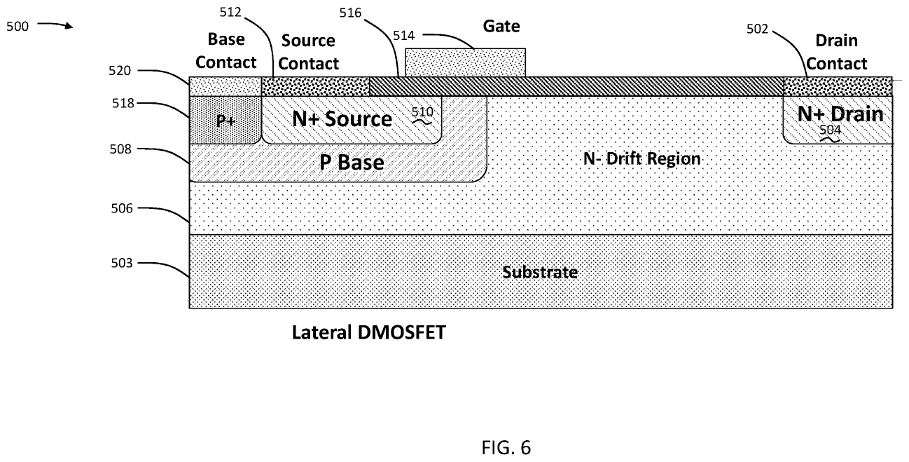

Referring to FIG. 6, a cross sectional view of a lateral DMOSFET is shown. The description provided above for the DMOSFET in relationship with FIG. 3 applies to the lateral DMOSFET device of FIG. 6 with the apparent differences (e.g., drain and source semiconductor regions are laterally juxtaposed as well as the associated source and drain electrodes, shown in FIG. 6 as “Contacts”).

The MOS lateral power device 500 includes a drain electrode 502 (identified as “Drain Contact”) in electrical contact with a drain semiconductor region 504 (shown as “N+ Drain Region”) of a first conductivity type (N type shown, however as explained below the first conductivity type can be P type while a second conductivity type can be N type). The material of the drain semiconductor region 504 can be doped silicon, doped silicon carbide, or other suitable semiconductor material. More is discussed below regarding the doping level. The MOS lateral power device 500 includes a substrate 503 (identified as “Substrate”). The MOS Power device 500 also includes a drift semiconductor region 506 of a first conductivity type (shown as “N-Drift Region”, however as explained below the first conductivity type can be P type while a second conductivity type can be N type). The drift semiconductor region 506 is coupled to the substrate 503. The material of the drift semiconductor region 506 can be doped silicon, doped silicon carbide, or other suitable semiconductor material. The MOS lateral power device 500 further includes a base semiconductor region 508 of the second conductivity type (shown as “P Base”, however as explained below the second conductivity type can be N type while the first conductivity type can be P type). The base semiconductor region 508 is coupled to the drift semiconductor region 506 and isolated from the drift semiconductor region 506 by the pn junction at the interface between these two regions. The material of the base semiconductor region 508 can be doped silicon, silicon carbide, or other suitable semiconductor material. The MOS lateral power device 500 further includes a source semiconductor region 510 of the first conductivity type (shown as “N+ Source”, however as explained below the first conductivity type can be P type while the second conductivity type can be N type). The source semiconductor region 510 is coupled to the base semiconductor region 508 and isolated by the base semiconductor region 508 from the drift semiconductor region 506. The material of the source semiconductor region 510 can be doped silicon, doped silicon carbide, or other suitable semiconductor material. The MOS lateral power device 500 further includes a source electrode 512 (shown as “Source Contact”) that is coupled to the source semiconductor region 510, making electrical contact therewith. The MOS lateral power device 500 further includes a gate electrode 514 (shown simply as “Gate”) that is provided adjacent at least a portion of but isolated from i) the base semiconductor region 508, ii) the source semiconductor region 510, and iii) the drift semiconductor region 506 by a dielectric material 516. The dielectric material 516 has a thickness between 1 nm and 30 nm (or between 1 nm and 25 nm, or between 1 nm and 20 nm, or between 1 nm and 15 nm, or between 1 nm and 10 nm, or between 1 and 5 nm) multiplied by a correction factor defined as a ratio of dielectric permittivity of the dielectric material and the permittivity of silicon dioxide. The drift semiconductor region 506 has a sufficient lateral dimension and doping to withstand greater than e.g., 100 V (this value depends on the semiconductor material—in silicon the drift region may only be designed to withstand greater than 20-30 V; in SiC, the drift region typically withstands more than 400-500 V; and GaN is above 50-100 V) between the drain electrode 502 and the source electrode 512 when substantially no current is flowing through the drain electrode 502. The MOS lateral power device 500 further includes a semiconductor region 518 of the second conductivity type (shown as “P+”, however as explained below the second conductivity type can be N type while the first conductivity type can be P type). The semiconductor region 518 is coupled to the base semiconductor region 508 and isolated by the base semiconductor region 508 from the drift semiconductor region 506. The material of the semiconductor region 518 can be doped silicon, doped silicon carbide, or other suitable semiconductor material. The MOS lateral power device 500 further includes a base contact 520 (shown as “Base Contact”) that is coupled to the semiconductor region 518, making electrical contact therewith.

If the gate-to-source voltage (V_{GS}) is above the threshold voltage V_{T}, a conducting channel (not shown, but known to a person having ordinary skill in the art) is induced along the surface of the semiconductor under the gate and the power device turns on. The gate insulator (i.e., the material 516) is a dielectric, and the most common dielectric is SiO₂. Other dielectric materials could also be used, for example Al₂O₃, Si₃N₄, HfO₂, ZrO₂, or layered combinations thereof.

Each dielectric material can be characterized in terms of two electric fields, the breakdown field (i.e., critical field) E_{CR} where the dielectric fails and no longer acts as an insulator, and the maximum reliable field E_{REL} beyond which the dielectric does not satisfy long-term reliability requirements. For SiO₂, E_{CR} is about 10 MV/cm and E_{REL} is about 4 MV/cm. Other dielectrics can each be characterized with particular values for E_{CR} and E_{REL}.

In the event of a short circuit, shown as a dashed line in FIG. 2 in the load 152, a high internal power dissipation occurs which causes extremely rapid adiabatic heating of the power device 100 or 500. The generated heat does not have sufficient time to diffuse outward to any attached cooling apparatus (e.g. a heat sink) via normal thermal conduction before the device fails. The temperature rise ΔT that occurs inside the device during a short-circuit event of duration t_{sc} seconds can therefore be estimated as provided be equation (1) provided above.

In the MOS lateral power device 500 shown in FIG. 6, the dielectric material 516 includes one or more layers of silicon dioxide, aluminum oxide, zirconium oxide, hafnium oxide, gallium oxide, lanthanum oxide, lanthanum aluminum oxide, and beryllium oxide.

In the MOS lateral power device shown in FIG. 6, the material of the source, drain, and gate electrodes 512, 514, and 502, respectively, includes one or more of copper, silver, gold, carbon, graphite, nickel, titanium, aluminum, polysilicon, and graphene. According to one embodiment, the ohmic metal used on N-type regions such as the source and drain is nickel. The ohmic metal used on P-type regions such as the base is aluminum or nickel. It should be appreciated that these metals are used in SiC, while other metals may be used for other MOSFETs such as silicon MOSFETs and GaN MOSFETs. These metals are annealed at a high temperature, e.g., about 1000° C.—however, lower temperatures may be acceptable for various other semiconductor material, e.g., GaN—to form ohmic contacts, then they are covered with a thick (4-5 μm) conductive metal such as aluminum. A thin layer of titanium is typically used for adhesion, covered with a thicker layer of aluminum containing about 0.5% copper.

The material for the substrate 503 can be any one of Si, SiC, graphene, glass, sapphire, ceramic, or other suitable substrates known to a person having ordinary skill in the art.

In the MOS lateral power device 500 shown in FIG. 6, the drift semiconductor region 506 is in contact with the substrate 503.

In the MOS lateral power device 500 shown in FIG. 6, the base semiconductor region 508 is in contact with the drift semiconductor region 506.

In the MOS lateral power device 500 shown in FIG. 6, the source semiconductor region 510 is in contact with the base semiconductor region 508.

In the MOS lateral power device 500 shown in FIG. 6, the first conductivity type is N-type and the second conductivity type is P-type.

In the MOS lateral power device 500 shown in FIG. 6, the first conductivity type is P-type and the second conductivity type is N-type.

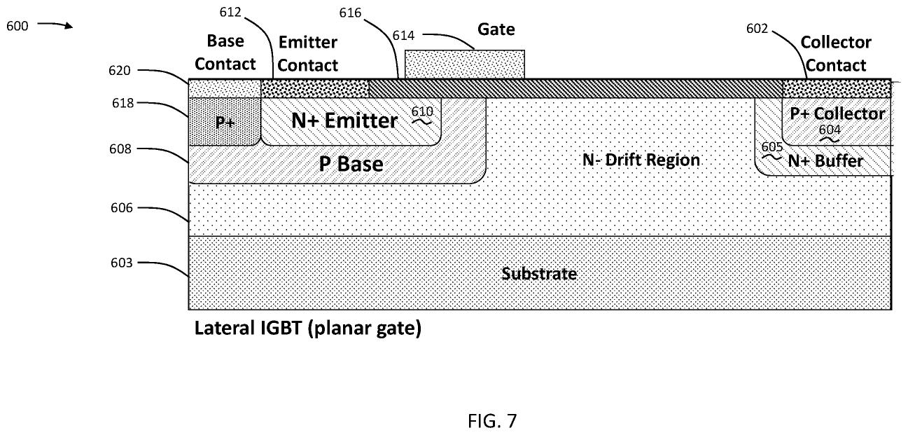

Referring to FIG. 7, a cross sectional view of a lateral IGBT is shown. The description provided above for the IGBT in relationship with FIG. 4 applies to the lateral IGBT device of FIG. 7 with the apparent differences (e.g., emitter and collector semiconductor regions are laterally juxtaposed as well as the associated emitter and collector electrodes, shown in FIG. 7 as “Contacts”).

Referring to FIG. 7, the lateral IGBT power device 600 includes a collector electrode 602 in electrical contact with a collector semiconductor region 604 (shown as “P+ Collector”) of a first conductivity type (P type shown, however as explained below the first conductivity type can be N type while a second conductivity type can be P type). The material of the collector semiconductor region 604 can be doped silicon, doped silicon carbide, or other suitable semiconductor material. More is discussed below regarding the doping level. The lateral IGBT power device 600 further includes a substrate 603 (shown as “Substrate”). The lateral IGBT power device 600 further includes a drift semiconductor region 606 of the second conductivity type (shown as “N-Drift Region”, however as explained below the first conductivity type can be N type while a second conductivity type can be P type). The drift semiconductor region 606 is coupled to the collector semiconductor region 604 via a buffer layer 605 (identified as “N+ Buffer”) of the second conductivity type (however, as explained below the first conductivity type can be N type while the second conductivity type can be P type). The material of the drift semiconductor region 606 can be doped silicon, doped silicon carbide, or other suitable semiconductor material. The lateral IGBT power device 600 further includes a base semiconductor region 608 of the first conductivity type (shown as “P Base”, however as explained below the second conductivity type can be p type while the first conductivity type can be N type). The base semiconductor region 608 is coupled to the drift semiconductor region 606 and isolated by the drift semiconductor region 606 from the collector semiconductor region 604. The material of the base semiconductor region 608 can be doped silicon, doped silicon carbide, or other suitable semiconductor material. The lateral IGBT power device 600 further includes an emitter semiconductor region 610 of the second conductivity type (shown as “N+ Emitter”, however as explained below the first conductivity type can be N type while the second conductivity type can be P type). The emitter semiconductor region 610 is coupled to the base semiconductor region 608 and isolated by the base semiconductor region 608 from the drift semiconductor region 606. The material of the emitter semiconductor region 610 can be doped silicon, doped silicon carbide, or other suitable semiconductor material. The lateral IGBT power device 600 further includes an emitter electrode 612 (shown as “Emitter Contact”) that is coupled to the emitter semiconductor region 610, making electrical contact therewith. The lateral IGBT power device 600 further includes a gate electrode 614 (shown simply as “Gate”) that is provided adjacent at least a portion of but isolated from i) the base semiconductor region 608, ii) the emitter semiconductor region 610, and iii) the drift semiconductor region 606 by a dielectric material 616. The dielectric material 616 has a thickness between 1 nm and 30 nm (or between 1 nm and 25 nm, or between 1 nm and 20 nm, or between 1 nm and 15 nm, or between 1 nm and 10 nm, or between 1 and 5 nm) multiplied by a correction factor defined as a ratio of dielectric permittivity of the dielectric material and the permittivity of silicon dioxide. The drift semiconductor region 606 has a sufficient lateral dimension and doping to withstand greater than e.g., 100 V (this value depends on the semiconductor material—in silicon the drift region may only be designed to withstand greater than 20-30 V; in SiC, the drift region typically withstands more than 400-500 V; and GaN is above 50-100 V) between the collector electrode 602 and the emitter electrode 612 when substantially no current is flowing through the collector electrode 602. The lateral IGBT power device 600 further includes a semiconductor region 618 of the first conductivity type (shown as “P+”, however as explained below the second conductivity type can be P type while the first conductivity type can be N type). The semiconductor region 618 is coupled to the base semiconductor region 608 and isolated by the base semiconductor region 608 from the drift semiconductor region 606. The material of the semiconductor region 618 can be doped silicon, doped silicon carbide, or other suitable semiconductor material. The lateral IGBT power device 600 further includes a base contact 620 (shown as “Base Contact”) that is coupled to the semiconductor region 618, making electrical contact therewith.

The gate insulator (i.e., the material 616) is a dielectric, and the most common dielectric is SiO₂. Other dielectric materials could also be used, for example Al₂O₃, Si₃N₄, HfO₂, ZrO₂, or layered combinations thereof.

Each dielectric material can be characterized in terms of two electric fields, the breakdown field (i.e., critical field) E_{CR} where the dielectric fails and no longer acts as an insulator, and the maximum reliable field E_{REL} beyond which the dielectric does not satisfy long-term reliability requirements. For SiO₂, E_{CR} is about 10 MV/cm and E_{REL} is about 4 MV/cm. Other dielectrics can each be characterized with particular values for E_{CR} and E_{REL}.

In the event of a short circuit, shown as a dashed line in FIG. 2 in the load 152, a high internal power dissipation occurs which causes extremely rapid adiabatic heating of the power device 100 or 600. The generated heat does not have sufficient time to diffuse outward to any attached cooling apparatus (e.g. a heat sink) via normal thermal conduction before the device fails. The temperature rise ΔT that occurs inside the device during a short-circuit event of duration t_{sc} seconds can therefore be estimated as provide in equation (1) above.

In the lateral IGBT power device 600 shown in FIG. 7, the dielectric material 616 includes one or more layers of silicon dioxide, aluminum oxide, zirconium oxide, hafnium oxide, gallium oxide, lanthanum oxide, lanthanum aluminum oxide, and beryllium oxide.

In the lateral IGBT power device 600 shown in FIG. 7, the material of the emitter, collector, and gate electrodes 612, 614, and 602, respectively, includes one or more of copper, silver, gold, carbon, graphite, nickel, titanium, aluminum, polysilicon, and graphene. According to one embodiment, the ohmic metal used on N-type regions such as the emitter and collector is nickel. The ohmic metal used on P-type regions such as the base is aluminum or nickel. It should be appreciated that these metals are used in SiC, while other metals may be used for other MOSFETs such as silicon MOSFETs and GaN MOSFETs. These metals are annealed at a high temperature, e.g., about 1000° C.—however, lower temperatures may be acceptable for various other semiconductor material, e.g., GaN—to form ohmic contacts, then they are covered with a thick (4-5 μm) conductive metal such as aluminum. A thin layer of titanium is typically used for adhesion, covered with a thicker layer of aluminum containing about 0.5% copper.

In the lateral IGBT power device 600 shown in FIG. 7, the buffer layer 605 is in contact with the collector semiconductor region 604.

In the lateral IGBT power device 600 shown in FIG. 7, the drift semiconductor region 606 is in contact with the buffer layer 605 and the substrate 603.

In the lateral IGBT power device 600 shown in FIG. 7, the base semiconductor region 608 is in contact with the drift semiconductor region 606.

In the lateral IGBT power device 600 shown in FIG. 7, the emitter semiconductor region 610 is in contact with the base semiconductor region 608.

In the lateral IGBT power device 600 shown in FIG. 7, the first conductivity type is P type and the second conductivity type is N type.

In the lateral IGBT power device 600 shown in FIG. 7, the first conductivity type is N type and the second conductivity type is P type.

In the lateral IGBT power device 600 shown in FIG. 7, the collector semiconductor region 604 has a dopant level higher than a dopant level of the drift semiconductor region 606.

In the lateral IGBT power device 600 shown in FIG. 7, the emitter semiconductor region 610 has a dopant level higher than a dopant level of the drift semiconductor region 606.

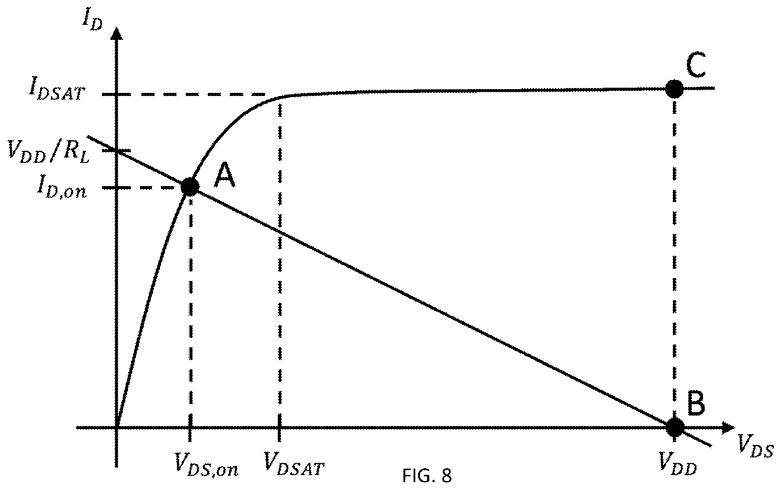

Referring to FIG. 8, a graph of drain current I_{D} of a MOSFET as a function of V_{DS} for a gate voltage greater than the threshold voltage V_{T} is illustrated. There are two distinct regions of operation, the linear region, also called the ohmic region where the I_{DS} (shown as I_{D}) current is linearly related to the V_{DS} where V_{DS}<V_{DSAT}; and the saturation region (V_{DS}>V_{DSAT}) where the current becomes roughly constant regardless of the V_{DS}. The normal on-state, point A, occurs in the linear region while the normal off state occurs at point B with V_{GS}<V_{T}. The short-circuit condition occurs at point C, with the drain current equal to the saturation current I_{DSAT}, and the drain voltage substantially equal to the supply voltage (V_{DD}, see FIG. 2), which could be as high as the maximum rated drain voltage of the power device.

In one exemplary situation where the supply voltage is half the maximum rated drain voltage, equation (1) can be rewritten as:

$$Δ T = \frac{{I}_{DSAT} {V}_{BR}}{2 ρ {C}_{p} V} {t}_{s c} \qquad ( 2 )$$

where V_{BR} is the blocking voltage of the device. The heated volume of a power device is approximately equal to the product of the active area and the thickness of the voltage blocking layer (V=A×d). The thickness in a typical power MOSFET is proportional to the required blocking voltage V_{BR}, and inversely proportional to the critical electric field of the semiconductor material: d=2 V_{DR}/E_{CR}. Rewriting current density as a function of I_{DSAT}, J_{DSAT}=I_{DSAT}/A, equation (2) can be rewritten as:

$$Δ T = \frac{{E}_{CR} {J}_{DSAT}}{4 ρ {C}_{p}} {t}_{s c} . \qquad ( 3 )$$

Solving equation (3) for the short-circuit withstand time t_{sc}:

$${t}_{s c} = \frac{4 ρ {C}_{p} Δ T}{{E}_{CR} {J}_{DSAT}} . \qquad ( 4 )$$

From this equation, it can be observed that the short-circuit withstand time of a power MOSFET is inversely proportional to the saturation current density. Minimizing this parameter will therefore improve robustness to short circuit events.

Devices are typically rated by their on-resistance, which is the reciprocal of the slope of the nearly linear region of the I_{D}−V_{DS} plot shown in FIG. 8, from the origin to the operating point A. As discussed above and shown in FIG. 3, the on-resistance of a power device is the sum of several components, including the channel resistance R_{ch} 224, drift or blocking layer resistance 228, substrate resistance 230, etc. Of these, for SiC power MOSFETs with blocking voltages less than about 1 kV, the channel resistance becomes dominant, and is given by the following equation, when normalized to total device area:

$${R}_{ch , sp} = {R}_{c h} A = \frac{{L}_{c h} A}{{μ}_{n} {W}_{c h} {C}_{o x} ( {V}_{G S} - {V}_{T} )} , \qquad ( 5 )$$

where L_{ch} and W_{ch} are the length and width of the MOSFET channel,
A is the device area,
μₙ is the mobility of electrons in the channel,
Cₒₓ is the capacitance of the gate insulator per unit area,
V_{GS} is the gate-to-source voltage, and
V_{T} is the threshold voltage. The saturation current density, in the simplest form, is given by:

$${J}_{DSAT} = \frac{{μ}_{n} {W}_{c h} {{C}_{o x} ( {V}_{G S} - {V}_{T} )}^{2}}{2 {L}_{c h} A} = \frac{{V}_{G S} - {V}_{T}}{2 {R}_{ch , sp}} \qquad ( 6 )$$

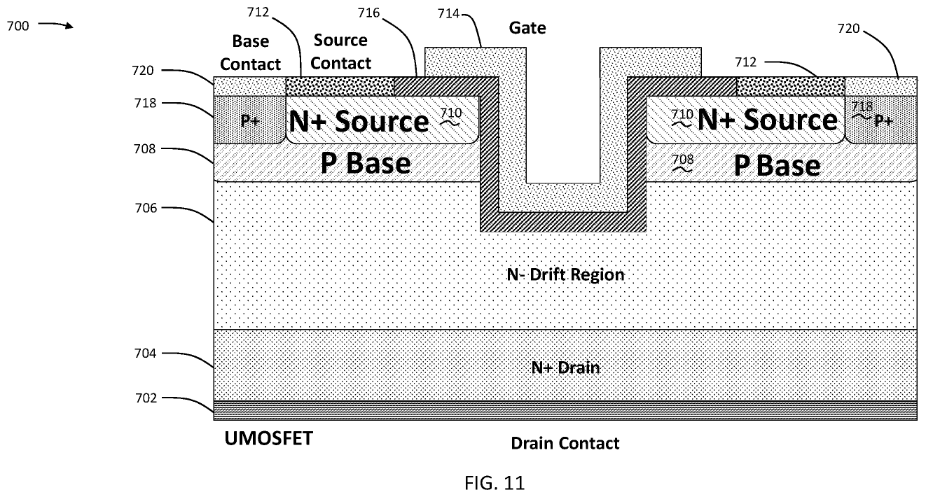

To reduce the active area, and thus the cost, of a power MOSFET, device engineers can reduce R_{ch,sp} in a number of ways, for example by scaling the unit cell area of the device through sub-micron photolithography, or by adopting a more compact cell design such as the UMOSFET (example of which is shown in FIG. 11). However, anything that is done to reduce R_{ch,sp} also increases J_{DSAT}, and given the inverse proportionality thus reduces the short-circuit withstand time.

The saturation current density can be reduced by simply lowering the gate overdrive voltage V_{GS}−V_{T}, but this would normally increase the specific on-resistance by reducing the electron density in the channel, as shown by equation (5). However, simultaneously increasing Cₒₓ by the same factor, keeping the term Cₒₓ(V_{GS}−V_{T}) substantially constant, maintains the same R_{ch,sp}, but decreases J_{DSAT}, since J_{DSAT} depends on the square of the overdrive voltage. The gate insulator capacitance is given by

Cₒₓ=κₒₓϵ₀/tₒₓ (7),

where κₒₓ is the dielectric constant of the insulator, and tₒₓ is the thickness of the insulator. Therefore, the insulator capacitance can be increased by either replacing silicon dioxide, which has a dielectric constant of 3.9, with a high-K dielectric as has been done in high-performance Si CMOS transistors in recent years, or by simply reducing the thickness of the gate insulator. The typical gate oxide thickness in current SiC MOSFETs is 40-50 nm, leaving significant room for reduction before problems such as gate leakage become significant.

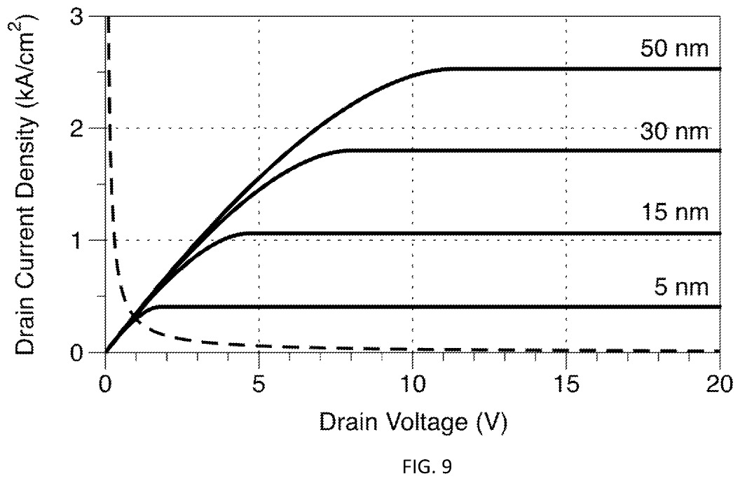

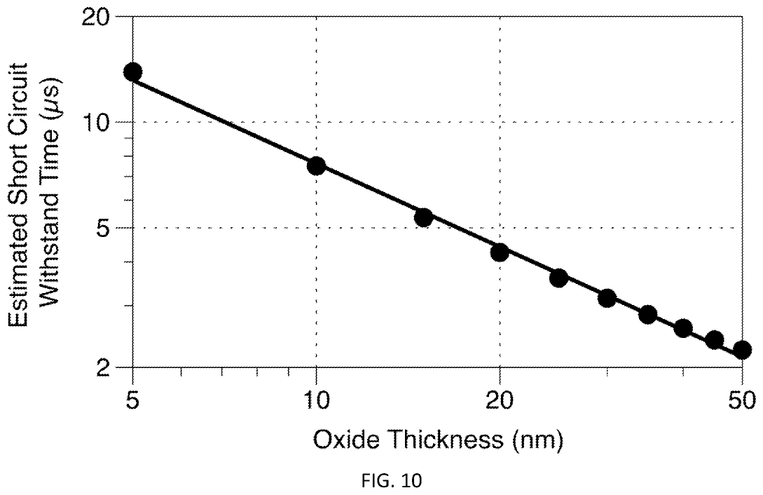

To illustrate the potential of this method of producing a more robust SiC power MOSFET, reference is made to FIG. 9 which shows calculated current density vs. drain voltage curves for a 900 V SiC DMOSFET with gate oxide thicknesses varying from 5-50 nm. With a reduction in oxide thickness, the gate voltage is lowered to maintain a constant oxide electric field, thus maintaining oxide reliability. As is clearly illustrated, reducing the oxide thickness from 50 nm to 5 nm would result in a factor of 6 reduction in J_{DSAT} (i.e., from about 3 to about 0.5 kA/cm² on the y-axis). It should be noted that the slope of the J-V curves near the origin, i.e. the specific on-resistance, does not change. Also plotted in FIG. 9 is a continuous power dissipation limit of 300 W/cm² (in dashed lines). The normal on-state operating point would be at the intersection of this power limit and the I-V curves. Note that the operating point does not change appreciatively as the oxide thickness is reduced. The only significant change is that the gate voltage must be reduced from about 27 V to about 9 V. Using equation 4, FIG. 10 shows the estimated increase in short circuit withstand time with this decrease in oxide thickness. This graph shows an inverse relationship between the short circuit withstand time and the thickness of the oxide. For example for oxide thickness of 5 nm, the short circuit withstand time can be as long as 15 μs. It should be understood that the specific values of short circuit withstand time cited above depend on the assumed maximum allowable temperature of the structure ΔT, and different assumed values of ΔT result in different values of short circuit withstand from those cited above.

Thus reducing the oxide thickness at the same time as reducing the gate drive voltage (V_{GS}−V_{T}) reduces J_{DSAT}, which increases the short-circuit withstand time, substantially unaffecting the R_{ch} which can impact the on resistance.

With reference to FIGS. 11, 12, and 13, cross sectional views of a UMOSFET, a superjunction UMOSFET, and an IGBT with trench gates are shown.

Referring To FIG. 11, a cross sectional view of a MOS power device 700, and in particular a UMOSFET, is shown. The MOS power device 700 includes a drain electrode 702 (identified as “Drain Contact”) in electrical contact with a drain semiconductor region 704 (shown as “N+ Drain”) of a first conductivity type (N type shown, however as explained below the first conductivity type can be P type while a second conductivity type be N type). The material of the drain semiconductor region 704 can be doped silicon, doped silicon carbide, or other suitable semiconductor material (e.g., gallium arsenide (GaAs) or gallium nitride (GaN)). More is discussed below regarding the doping level. The MOS Power device 700 also includes a drift semiconductor region 706 of the first conductivity type (shown as “N-Drift Region”, however as explained below the first conductivity type can be P type while the second conductivity type can be N type). The drift semiconductor region 706 is coupled to the drain semiconductor region 704. The material of the drift semiconductor region 706 can be doped silicon, doped silicon carbide, or other suitable semiconductor material (e.g., gallium arsenide (GaAs) or gallium nitride (GaN)). The MOS power device 700 further includes a base semiconductor region 708 of the second conductivity type (shown as “P Base”, however as explained below the second conductivity type can be N type while the first conductivity type can be P type). The base semiconductor region 708 is coupled to the drift semiconductor region 706 through the pn junction at the interface between these two regions. The material of the base semiconductor region 708 can be doped silicon, doped silicon carbide, or other suitable semiconductor material. The MOS power device 700 further includes a source semiconductor region 710 of the first conductivity type (shown as “N+ Source”, however as explained below the first conductivity type can be P type while the second conductivity type can be N type). The source semiconductor region 710 is coupled to the base semiconductor region 708 and isolated by the base semiconductor region 708 from the drift semiconductor region 706. The material of the source semiconductor region 710 can be doped silicon, doped silicon carbide, or other suitable semiconductor material. The MOS power device 700 further includes a source electrode 712 (shown as “Source Contact”) that is coupled to the source semiconductor region 710, making electrical contact therewith. The MOS power device 700 further includes a gate electrode 714 (shown simply as “Gate”) that is provided adjacent at least a portion of but isolated from i) the base semiconductor region 708, ii) the source semiconductor region 710, and iii) the drift semiconductor region 706 by a dielectric material 716. The dielectric material 716 has a thickness between 1 nm and 30 nm (or between 1 nm and 25 nm, or between 1 nm and 20 nm, or between 1 nm and 15 nm, or between 1 nm and 10 nm, or between 1 and 5 nm) multiplied by a correction factor defined as a ratio of dielectric permittivity of the dielectric material and the permittivity of silicon dioxide. The gate electrode 714 and the dielectric material 716 both are U-shaped, to be contrasted with the gate electrode 214 and the dielectric material 216 of the DMOSFET shown in FIG. 3. The drift semiconductor region 706 has a sufficient thickness and doping to withstand greater than e.g., 100 V (this value depends on the semiconductor material—in silicon the drift region may only be designed to withstand greater than 20-30 V; in SiC, the drift region typically withstands more than 400-500 V; and GaN is above 50-100 V) between the drain electrode 702 and the source electrode 712 when substantially no current is flowing through the drain electrode 702. The MOS power device 700 further includes a semiconductor region 718 of the second conductivity type (shown as “P+”, however as explained below the second conductivity type can be N type while the first conductivity type can be P type). The semiconductor region 718 is coupled to the base semiconductor region 708 and isolated by the base semiconductor region 708 from the drift semiconductor region 706. The material of the semiconductor region 718 can be doped silicon, doped silicon carbide, or other suitable semiconductor material. The MOS power device 700 further includes a base contact 720 (shown as “Base Contact”) that is coupled to the semiconductor region 718, making electrical contact therewith.

If the gate-to-source voltage (V_{GS}) is above the threshold voltage V_{T}, a conducting channel (not shown, but known to a person having ordinary skill in the art) is induced along the surface of the semiconductor under the gate and the power device turns on. The gate insulator (i.e., the dielectric material 716) is a dielectric, and the most common dielectric is SiO₂. Other dielectric materials could also be used, for example Al₂O₃, Si₃N₄, HfO₂, ZrO₂, or layered combinations thereof.

Each dielectric material can be characterized in terms of two electric fields, the breakdown field (i.e., critical field) E_{CR} where the dielectric fails and no longer acts as an insulator, and the maximum reliable field E_{REL} beyond which the dielectric does not satisfy long-term reliability requirements. For SiO₂, E_{CR} is about 10 MV/cm and E_{REL} is about 4 MV/cm. Other dielectrics can each be characterized with particular values for E_{CR} and E_{REL}.

In the event of a short circuit, shown as a dashed line in FIG. 2 in the load 152, a high internal power dissipation occurs which causes extremely rapid adiabatic heating of the power device 100 or 700. The generated heat does not have sufficient time to diffuse outward to any attached cooling apparatus (e.g. a heat sink) via normal thermal conduction before the device fails. The temperature rise ΔT that occurs inside the device during a short-circuit event of duration t_{sc} seconds can therefore be estimated by equation (1). The power dissipation is simply the current flowing in the device multiplied by the voltage across the drain and source terminals, i.e., P=I_{D}×V_{DS}.

In the MOS power device 700 shown in FIG. 11, the dielectric material 716 includes one or more layers of silicon dioxide, aluminum oxide, zirconium oxide, hafnium oxide, gallium oxide, lanthanum oxide, lanthanum aluminum oxide, beryllium oxide, or other suitable dielectric.

In the MOS power device 700 shown in FIG. 11, the material of the source, drain, and gate electrodes 712, 714, and 702, respectively, includes one or more of copper, silver, gold, carbon, graphite, nickel, titanium, aluminum, polysilicon, and graphene. According to one embodiment, the ohmic metal used on N-type regions such as the source and drain is nickel. The ohmic metal used on P-type regions such as the base is aluminum or nickel. It should be appreciated that these metals are used in SiC, while other metals may be used for other MOSFETs such as silicon MOSFETs and GaN MOSFETs. These metals are annealed at a high temperature, e.g., about 1000° C.—however, lower temperatures may be acceptable for various other semiconductor material, e.g., GaN—to form ohmic contacts, then they are covered with a thick (4-5 μm) conductive metal such as aluminum. A thin layer of titanium is typically used for adhesion, covered with a thicker layer of aluminum containing about 0.5% copper.

In the MOS power device 700 shown in FIG. 11, the drift semiconductor region 706 is in contact with the drain semiconductor region 704.

In the MOS power device 700 shown in FIG. 11, the base semiconductor region 708 is in contact with the drift semiconductor region 706.

In the MOS power device 700 shown in FIG. 11, the source semiconductor region 710 is in contact with the base semiconductor region 708.

In the MOS power device 700 shown in FIG. 11, the first conductivity type is N-type and the second conductivity type is P-type.

In the MOS power device 700 shown in FIG. 11, the first conductivity type is P-type and the second conductivity type is N-type.

In the MOS power device 700 shown in FIG. 11, the drain semiconductor region 704 has a dopant level higher than a dopant level of the drift semiconductor region 706.

In the MOS power device 700 shown in FIG. 11, the source semiconductor region 710 has a dopant level higher than a dopant level of the drift semiconductor region 706.

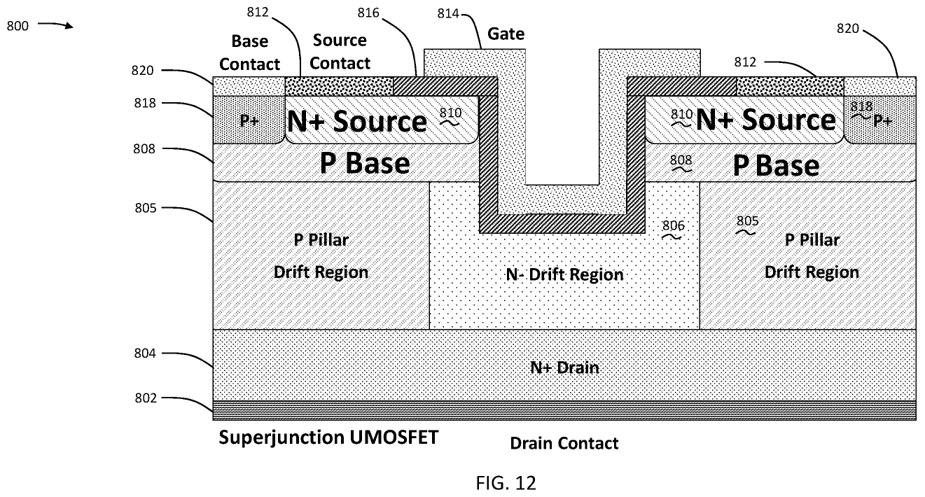

Referring to FIG. 12, a cross sectional view of a superjunction UMOSFET 800 is shown.

The MOS power device 800 includes a drain electrode 802 (identified as “Drain Contact”) in electrical contact with a drain semiconductor region 804 (shown as “N+ Drain”) of a first conductivity type (N type shown, however as explained below the first conductivity type can be P type while a second conductivity type can be N type). The material of the drain semiconductor region 804 can be doped silicon, doped silicon carbide, or other suitable semiconductor material. More is discussed below regarding the doping level. The MOS Power device 800 also includes alternating stacks, shown as “P Pillar”, “N Pillar”, and “P Pillar” of alternating conductivity types 805 and 806 of the second conductivity type and the first conductivity type (shown as “P Pillar Drift Region” and “N Pillar Drift Region”, however, as explained below the first conductivity type can be P type while a second conductivity type can be N type). The drift semiconductor regions 805 and 806 are coupled to the drain semiconductor region 804. The material of the drift semiconductor regions 805 and 806 can be doped silicon, doped silicon carbide, or other suitable semiconductor material. The MOS power device 800 further includes a base semiconductor region 808 of the second conductivity type (shown as “P Base”, however as explained below the second conductivity type can be N type while the first conductivity type can be P type). The base semiconductor region 808 is coupled to the drift semiconductor region 805 and isolated from the drain semiconductor region 804 by the pn junction at the interface between base region 808 and drift region 806. The material of the base semiconductor region 808 can be doped silicon, doped silicon carbide, or other suitable semiconductor material. The MOS power device 800 further includes a source semiconductor region 810 of the first conductivity type (shown as “N+ Source”, however as explained below the first conductivity type can be P type while the second conductivity type can be N type). The source semiconductor region 810 is coupled to the base semiconductor region 808 and isolated by the base semiconductor region 808 from the drift semiconductor regions 805 and 806. The material of the source semiconductor region 810 can be doped silicon, doped silicon carbide, or other suitable semiconductor material. The MOS power device 800 further includes a source electrode 812 (shown as “Source Contact”) that is coupled to the source semiconductor region 810, making electrical contact therewith. The MOS power device 800 further includes a gate electrode 814 (shown simply as “Gate”) that is provided adjacent at least a portion of but isolated from i) the base semiconductor region 808, ii) the source semiconductor region 810, and iii) the drift semiconductor region 806 by a dielectric material 816. The gate electrode 814 and the dielectric material 816 both are U-shaped, to be contrasted with the gate electrode 414 and the dielectric material 416 of the Superjunction DMOSFET shown in FIG. 5. The dielectric material 816 has a thickness between 1 nm and 30 nm (or between 1 nm and 25 nm, or between 1 nm and 20 nm, or between 1 nm and 15 nm, or between 1 nm and 10 nm, or between 1 and 5 nm) multiplied by a correction factor defined as a ratio of dielectric permittivity of the dielectric material and the permittivity of silicon dioxide. The drift semiconductor regions 805 and 806 have a sufficient thickness and doping to withstand greater than e.g., 100 V (this value depends on the semiconductor material—in silicon the drift region may only be designed to withstand greater than 20-30 V; in SiC, the drift region typically withstands more than 400-500 V; and GaN is above 50-100 V) between the drain electrode 802 and the source electrode 812 when substantially no current is flowing through the drain electrode 802. The MOS power device 800 further includes a semiconductor region 818 of the second conductivity type (shown as “P+ Source”, however as explained below the second conductivity type can be N type while the first conductivity type can be P type). The semiconductor region 818 is coupled to the base semiconductor region 808 and isolated by the base semiconductor region 808 from the drift semiconductor regions 805 and 806. The material of the semiconductor region 818 can be doped silicon, doped silicon carbide, or other suitable semiconductor material. The MOS power device 800 further includes a base contact 420 (shown as “Base Contact”) that is coupled to the semiconductor region 818, making electrical contact therewith.

If the gate-to-source voltage (V_{GS}) is above the threshold voltage V_{T}, a conducting channel (not shown, but known to a person having ordinary skill in the art) is induced along the surface of the semiconductor under the gate and the power device turns on. The gate insulator (i.e., the material 816) is a dielectric, and the most common dielectric is SiO₂. Other dielectric materials could also be used, for example Al₂O₃, Si₃N₄, HfO₂, ZrO₂, or layered combinations thereof.

Each dielectric material can be characterized in terms of two electric fields, the breakdown field (i.e., critical field) E_{CR} where the dielectric fails and no longer acts as an insulator, and the maximum reliable field E_{REL} beyond which the dielectric does not satisfy long-term reliability requirements. For SiO₂, E_{CR} is about 10 MV/cm and E_{REL} is about 4 MV/cm. Other dielectrics can each be characterized with particular values for E_{CR} and E_{REL}.

In the event of a short circuit, shown as a dashed line in FIG. 2 in the load 152, a high internal power dissipation occurs which causes extremely rapid adiabatic heating of the power device 100 or 800. The generated heat does not have sufficient time to diffuse outward to any attached cooling apparatus (e.g. a heat sink) via normal thermal conduction before the device fails. The temperature rise ΔT that occurs inside the device during a short-circuit event of duration t_{sc} seconds can therefore be estimated using equation (1) provided above.

In the MOS power device 800 shown in FIG. 12, the dielectric material 816 includes one or more layers of silicon dioxide, aluminum oxide, zirconium oxide, hafnium oxide, gallium oxide, lanthanum oxide, lanthanum aluminum oxide, and beryllium oxide.

In the MOS power device shown in FIG. 12, the material of the source, drain, and gate electrodes 812, 814, and 802, respectively, includes one or more of copper, silver, gold, carbon, graphite, nickel, titanium, aluminum, polysilicon, and graphene. According to one embodiment, the ohmic metal used on N-type regions such as the source and drain is nickel. The ohmic metal used on P-type regions such as the base is aluminum or nickel. It should be appreciated that these metals are used in SiC, while other metals may be used for other MOSFETs such as silicon MOSFETs and GaN MOSFETs. These metals are annealed at a high temperature, e.g., about 1000° C.—however, lower temperatures may be acceptable for various other semiconductor material, e.g., GaN—to form ohmic contacts, then they are covered with a thick (4-5 μm) conductive metal such as aluminum. A thin layer of titanium is typically used for adhesion, covered with a thicker layer of aluminum containing about 0.5% copper.

In the MOS power device 800 shown in FIG. 12, the drift semiconductor regions 805 and 806 are in contact with the drain semiconductor region 804.

In the MOS power device 800 shown in FIG. 12, the base semiconductor region 808 is in contact with the drift semiconductor regions 805 and 806.

In the MOS power device 800 shown in FIG. 12, the source semiconductor region 810 is in contact with the base semiconductor region 808.

In the MOS power device 800 shown in FIG. 12, the first conductivity type is N-type and the second conductivity type is P-type.

In the MOS power device 800 shown in FIG. 12, the first conductivity type is P-type and the second conductivity type is N-type.

In the MOS power device 800 shown in FIG. 12, the drain semiconductor region 804 has a dopant level higher than a dopant level of the drift semiconductor regions 805 or 806.

In the MOS power device 800 shown in FIG. 12, the source semiconductor region 810 has a dopant level higher than a dopant level of the drift semiconductor regions 805 or 806.

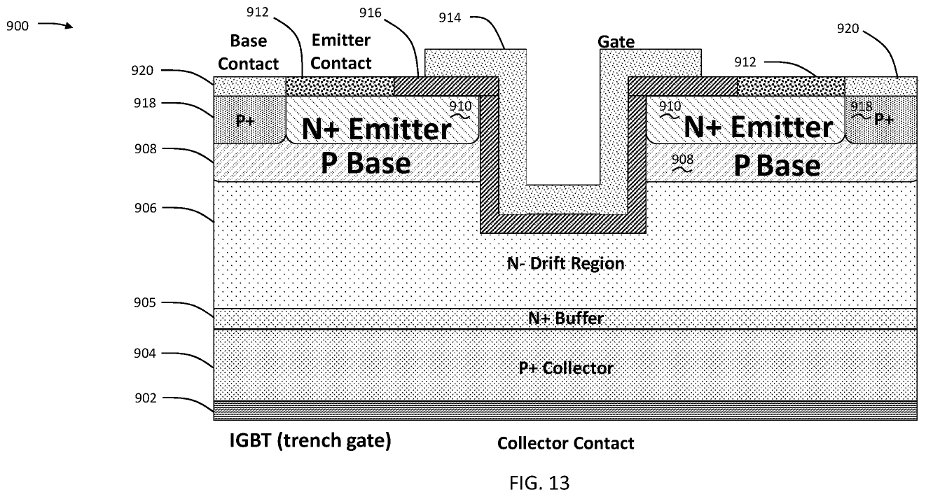

Referring to FIG. 13, a cross sectional view of a trench gate IGBT 900 is shown. The description provided for FIG. 13 is similar to the description for the vertical IGBT 300 provided in FIG. 4 with the difference that the gate electrode and the dielectric material are U-shaped, as will be discussed more fully below.

Referring to FIG. 13, the trench gate IGBT power device 900 includes a collector electrode 902 (shown as collector contact) in electrical contact with a collector semiconductor region 904 (shown as “P+ Collector”) of a first conductivity type (P type shown, however as explained below the first conductivity type can be N type while a second conductivity type can be P type). The material of the collector semiconductor region 904 can be doped silicon, doped silicon carbide, or other suitable semiconductor material. More is discussed below regarding the doping level. The trench gate IGBT power device 900 further includes a buffer layer 905 (shown as N+ Buffer) of the second conductivity type (N type shown, however as explained below the first conductivity type can be N type while the second conductivity type can be P type). The trench gate IGBT power device 900 also includes a drift semiconductor region 906 of the second conductivity type (shown as “N-Drift Region”, however as explained below the first conductivity type can be N type while a second conductivity type can be P type). The drift semiconductor region 906 is coupled to the collector semiconductor region 904 via the buffer layer 905. The material of the drift semiconductor region 906 can be doped silicon, doped silicon carbide, or other suitable semiconductor material. The trench gate IGBT power device 900 further includes a base semiconductor region 908 of the first conductivity type (shown as “P Base”, however as explained below the second conductivity type can be p type while the first conductivity type can be N type). The base semiconductor region 908 is coupled to the drift semiconductor region 906 through the pn junction at the interface between these two regions. The material of the base semiconductor region 908 can be doped silicon, doped silicon carbide, or other suitable semiconductor material. The trench gate IGBT power device 900 further includes an emitter semiconductor region 910 of the second conductivity type (shown as “N+ Emitter”, however as explained below the first conductivity type can be N type while the second conductivity type can be P type). The emitter semiconductor region 910 is coupled to the base semiconductor region 908 and isolated by the base semiconductor region 908 from the drift semiconductor region 906. The material of the emitter semiconductor region 910 can be doped silicon, doped silicon carbide, or other suitable semiconductor material. The trench gate IGBT power device 900 further includes an emitter electrode 912 (shown as “Emitter Contact”) that is coupled to the emitter semiconductor region 910, making electrical contact therewith. The trench gate IGBT power device 900 further includes a gate electrode 914 (shown simply as “Gate”) that is provided adjacent at least a portion of but isolated from i) the base semiconductor region 908, ii) the emitter semiconductor region 910, and iii) the drift semiconductor region 906 by a dielectric material 916. The gate electrode 914 and the dielectric material 916 both are U-shaped, to be contrasted with the gate electrode 314 and the dielectric material 316 of the vertical IGBT shown in FIG. 4. The dielectric material 916 has a thickness between 1 nm and 30 nm (or between 1 nm and 25 nm, or between 1 nm and 20 nm, or between 1 nm and 15 nm, or between 1 nm and 10 nm, or between 1 and 5 nm) multiplied by a correction factor defined as a ratio of dielectric permittivity of the dielectric material and the permittivity of silicon dioxide. The drift semiconductor region 906 has a sufficient thickness and doping to withstand greater than e.g., 100 V (this value depends on the semiconductor material—in silicon the drift region may only be designed to withstand greater than 20-30 V; in SiC, the drift region typically withstands more than 400-500 V; and GaN is above 50-100 V) between the collector electrode 902 and the emitter electrode 912 when substantially no current is flowing through the collector electrode 902. The trench gate IGBT power device 900 further includes a semiconductor region 918 of the first conductivity type (shown as “P+”, however as explained below the second conductivity type can be P type while the first conductivity type can be N type). The semiconductor region 918 is coupled to the base semiconductor region 908. The material of the semiconductor region 918 can be doped silicon, doped silicon carbide, or other suitable semiconductor material. The trench gate IGBT power device 900 further includes a base contact 920 (shown as “Base Contact”) that is coupled to the semiconductor region 918, making electrical contact therewith.

The gate insulator (i.e., the dielectric material 916) is a dielectric, and the most common dielectric is SiO₂. Other dielectric materials could also be used, for example Al₂O₃, Si₃N₄, HfO₂, ZrO₂, or layered combinations thereof.

Each dielectric material can be characterized in terms of two electric fields, the breakdown field (i.e., critical field) E_{CR} where the dielectric fails and no longer acts as an insulator, and the maximum reliable field E_{REL} beyond which the dielectric does not satisfy long-term reliability requirements. For SiO₂, E_{CR} is about 10 MV/cm and E_{REL} is about 4 MV/cm. Other dielectrics can each be characterized with particular values for E_{CR} and E_{REL}.

In the event of a short circuit, shown as a dashed line in FIG. 2 in the load 152, a high internal power dissipation occurs which causes extremely rapid adiabatic heating of the power device 100 or 900. The generated heat does not have sufficient time to diffuse outward to any attached cooling apparatus (e.g. a heat sink) via normal thermal conduction before the device fails. The temperature rise ΔT that occurs inside the device during a short-circuit event of duration t_{sc} seconds can therefore be estimated as provide in equation (1) above.

In the trench gate IGBT power device 900 shown in FIG. 13, the dielectric material 916 includes one or more layers of silicon dioxide, aluminum oxide, zirconium oxide, hafnium oxide, gallium oxide, lanthanum oxide, lanthanum aluminum oxide, beryllium oxide, or other suitable materials.

In the trench gate IGBT power device 900 shown in FIG. 13, the material of the emitter, collector, and gate electrodes 912, 914, and 902, respectively, includes one or more of copper, silver, gold, carbon, graphite, nickel, titanium, aluminum, polysilicon, and graphene. According to one embodiment, the ohmic metal used on N-type regions such as the emitter and collector is nickel. It should be appreciated that these metals are used in SiC, while other metals may be used for other MOSFETs such as silicon MOSFETs and GaN MOSFETs. These metals are annealed at a high temperature, e.g., about 1000° C.—however, lower temperatures may be acceptable for various other semiconductor material, e.g., GaN—to form ohmic contacts, then they are covered with a thick (4-5 μm) conductive metal such as aluminum. A thin layer of titanium is typically used for adhesion, covered with a thicker layer of aluminum containing about 0.5% copper.

In the trench gate IGBT power device 900 shown in FIG. 13, the buffer layer 905 is in contact with the collector semiconductor region 904.

In the trench gate IGBT power device 900 shown in FIG. 13, the drift semiconductor region 906 is in contact with the buffer layer 905.

In the trench gate IGBT power device 900 shown in FIG. 13, the base semiconductor region 908 is in contact with the drift semiconductor region 906.

In the trench gate IGBT power device 900 shown in FIG. 13, the emitter semiconductor region 910 is in contact with the base semiconductor region 908.

In the trench gate IGBT power device 900 shown in FIG. 13, the first conductivity type is P type and the second conductivity type is N type.

In the trench gate IGBT power device 900 shown in FIG. 13, the first conductivity type is N type and the second conductivity type is P type.

In the trench gate IGBT power device 900 shown in FIG. 13, the collector semiconductor region 904 has a dopant level higher than a dopant level of the drift semiconductor region 906.

In the trench gate IGBT power device 900 shown in FIG. 13, the emitter semiconductor region 910 has a dopant level higher than a dopant level of the drift semiconductor region 906.

Those having ordinary skill in the art will recognize that numerous modifications can be made to the specific implementations described above. The implementations should not be limited to the particular limitations described. Other implementations may be possible.

1. A silicon carbide (SiC) metal-oxide-semiconductor (MOS) power device, comprising:
an SiC drain semiconductor region of a first conductivity type;
an SiC drift semiconductor region of the first conductivity type coupled to the SiC drain semiconductor region;
an SiC base semiconductor region of a second conductivity type coupled to the SiC drift semiconductor region and isolated by the SiC drift semiconductor region from the SiC drain semiconductor region;
an SiC source semiconductor region of the first conductivity type coupled to the SiC base semiconductor region and isolated by the SiC base semiconductor region from the SiC drift semiconductor region;
a source electrode coupled to the SiC source semiconductor region;
a drain electrode coupled to the SiC drain semiconductor region;
a gate electrode provided adjacent at least a portion of but isolated from i) the SiC base semiconductor region, ii) the SiC source semiconductor region, and iii) the SiC drift semiconductor region by a dielectric material,
wherein voltage of the gate electrode with respect to the SiC base semiconductor region is less than or equal to about 12 V and thickness of the dielectric material is such that the electric field in the dielectric material is about 4 MV/cm when said gate voltage is about 12 V.

2. The SiC MOS power device of claim 1, wherein the dielectric material is silicon dioxide.

3. The SiC MOS power device of claim 1, wherein the material of the source, drain, and gate electrodes comprises one or more of copper, silver, gold, carbon, graphite, nickel, titanium, aluminum, polysilicon, and graphene.

4. The SiC MOS power device of claim 1, wherein the first conductivity type is N-type and the second conductivity type is P-type.

5. The SiC MOS power device of claim 1, wherein the first conductivity type is P-type and the second conductivity type is N-type.

6. The SiC MOS power device of claim 1, wherein the SiC drain semiconductor region has a dopant level higher than a dopant level of the SiC drift semiconductor region.

7. The SiC MOS power device of claim 1, wherein the SiC source semiconductor region has a dopant level higher than a dopant level of the SiC drift semiconductor region.

8. The SiC MOS power device of claim 1, wherein voltage of the gate electrode with respect to the SiC base semiconductor region is less than or equal to about 11 V and thickness of the dielectric material is such that the electric field in the dielectric material is about 4 MV/cm when said gate voltage is about 11 V.

9. The SiC MOS power device of claim 1, wherein voltage of the gate electrode with respect to the SiC base semiconductor region is less than or equal to about 10 V and thickness of the dielectric material is such that the electric field in the dielectric material is about 4 MV/cm when said gate voltage is about 10 V.

10. The SiC MOS power device of claim 1, wherein voltage of the gate electrode with respect to the SiC base semiconductor region is less than or equal to about 9 V and thickness of the dielectric material is such that the electric field in the dielectric material is about 4 MV/cm when said gate voltage is about 9 V.

11. A silicon carbide (SiC) insulated-gate bipolar transistor (IGBT) power device, comprising:
an SiC collector semiconductor region of a first conductivity type;
an SiC drift semiconductor region of the second conductivity type coupled to the SiC collector semiconductor region;
an SiC base semiconductor region of a first conductivity type coupled to the SiC drift semiconductor region and isolated by the SiC drift semiconductor region from the SiC collector semiconductor region;
an SiC emitter semiconductor region of the second conductivity type coupled to the SiC base semiconductor region and isolated by the SiC base semiconductor region from the SiC drift semiconductor region;
an emitter electrode coupled to the SiC emitter semiconductor region;
a collector electrode coupled to the SiC collector semiconductor region;
a gate electrode provided adjacent at least a portion of but isolated from i) the SiC base semiconductor region, ii) the SiC emitter semiconductor region, and iii) the SiC drift semiconductor region by a dielectric material,
wherein voltage of the gate electrode with respect to the SiC base semiconductor region is less than or equal to about 12 V and thickness of the dielectric material is such that the electric field in the dielectric material is about 4 MV/cm when said gate voltage is about 12 V.

12. The SiC IGBT power device of claim 11, wherein the dielectric material is silicon dioxide.

13. The SiC IGBT power device of claim 11, wherein the material of the source, drain, and gate electrodes comprises one or more of copper, silver, gold, carbon, graphite, nickel, titanium, aluminum, polysilicon, and graphene.

14. The SiC IGBT power device of claim 11, wherein the first conductivity type is N-type and the second conductivity type is P-type.

15. The SiC IGBT power device of claim 11, wherein the first conductivity type is P-type and the second conductivity type is N-type.

16. The SiC IGBT power device of claim 11, wherein the SiC collector semiconductor region has a dopant level higher than a dopant level of the SiC drift semiconductor region.

17. The SiC IGBT power device of claim 11, wherein the SiC emitter semiconductor region has a dopant level higher than a dopant level of the SiC drift semiconductor region.

18. The SiC IGBT power device of claim 11, wherein voltage of the gate electrode with respect to the SiC base semiconductor region is less than or equal to about 11 V and thickness of the dielectric material is such that the electric field in the dielectric material is about 4 MV/cm when said gate voltage is about 11 V.

19. The SiC IGBT power device of claim 11, wherein voltage of the gate electrode with respect to the SiC base semiconductor region is less than or equal to about 10 V and thickness of the dielectric material is such that the electric field in the dielectric material is about 4 MV/cm when said gate voltage is about 10 V.

20. The SiC IGBT power device of claim 11, wherein voltage of the gate electrode with respect to the SiC base semiconductor region is less than or equal to about 9 V and thickness of the dielectric material is such that the electric field in the dielectric material is about 4 MV/cm when said gate voltage is about 9 V.

21. A silicon carbide (SiC) metal-oxide-semiconductor (MOS) power device, comprising:
an SiC drain semiconductor region of a first conductivity type;
an SiC drift semiconductor region of the first conductivity type coupled to the SiC drain semiconductor region;
an SiC base semiconductor region of a second conductivity type coupled to the SiC drift semiconductor region and isolated by the SiC drift semiconductor region from the SiC drain semiconductor region;
an SiC source semiconductor region of the first conductivity type coupled to the SiC base semiconductor region and isolated by the SiC base semiconductor region from the SiC drift semiconductor region;
a source electrode coupled to the SiC source semiconductor region;
a drain electrode coupled to the SiC drain semiconductor region;
a gate electrode provided adjacent at least a portion of but isolated from i) the SiC base semiconductor region, ii) the SiC source semiconductor region, and iii) the SiC drift semiconductor region by a dielectric material,
wherein voltage of the gate electrode with respect to the SiC base semiconductor region is less than or equal to about 12 V and thickness of the dielectric material is such that the electric field in the dielectric material is between 2 MV/cm to 3.6 MV/cm when said gate voltage is about 12 V.

22. The SiC MOS power device of claim 21, wherein voltage of the gate electrode with respect to the SiC base semiconductor region is less than or equal to about 11 V and thickness of the dielectric material is such that the electric field in the dielectric material is between 2 MV/cm to 3.6 MV/cm when said gate voltage is about 11 V.

23. The SiC MOS power device of claim 21, wherein voltage of the gate electrode with respect to the SiC base semiconductor region is less than or equal to about 10 V and thickness of the dielectric material is such that the electric field in the dielectric material is between 2 MV/cm to 3.6 MV/cm when said gate voltage is about 10 V.

24. The SiC MOS power device of claim 21, wherein voltage of the gate electrode with respect to the SiC base semiconductor region is less than or equal to about 9 V and thickness of the dielectric material is such that the electric field in the dielectric material is between 2 MV/cm to 3.6 MV/cm when said gate voltage is about 9 V.

25. A silicon carbide (SiC) insulated-gate bipolar transistor (IGBT) power device, comprising:
an SiC collector semiconductor region of a first conductivity type;
an SiC drift semiconductor region of the second conductivity type coupled to the SiC collector semiconductor region;
an SiC base semiconductor region of a first conductivity type coupled to the SiC drift semiconductor region and isolated by the SiC drift semiconductor region from the SiC collector semiconductor region;
an SiC emitter semiconductor region of the second conductivity type coupled to the SiC base semiconductor region and isolated by the SiC base semiconductor region from the SiC drift semiconductor region;
an emitter electrode coupled to the SiC emitter semiconductor region;
a collector electrode coupled to the SiC collector semiconductor region;
a gate electrode provided adjacent at least a portion of but isolated from i) the SiC base semiconductor region, ii) the SiC emitter semiconductor region, and iii) the SiC drift semiconductor region by a dielectric material,
wherein voltage of the gate electrode with respect to the SiC base semiconductor region is less than or equal to about 12 V and thickness of the dielectric material is such that the electric field in the dielectric material is between 2 MV/cm to 3.6 MV/cm when said gate voltage is about 12 V.

26. The SiC IGBT power device of claim 25, wherein voltage of the gate electrode with respect to the SiC base semiconductor region is less than or equal to about 11 V and thickness of the dielectric material is such that the electric field in the dielectric material is between 2 MV/cm to 3.6 MV/cm when said gate voltage is about 11 V.

27. The SiC IGBT power device of claim 25, wherein voltage of the gate electrode with respect to the SiC base semiconductor region is less than or equal to about 10 V and thickness of the dielectric material is such that the electric field in the dielectric material is between 2 MV/cm to 3.6 MV/cm when said gate voltage is about 10 V.

28. The SiC IGBT power device of claim 25, wherein voltage of the gate electrode with respect to the SiC base semiconductor region is less than or equal to about 9 V and thickness of the dielectric material is such that the electric field in the dielectric material is between 2 MV/cm to 3.6 MV/cm when said gate voltage is about 9 V.
